(19) United States
(12) Patent Application Publication
(10) Pub. No.: US 2025/0063710 A1
(43) Pub. Date: Feb. 20, 2025

(54) NANOSHEET FIELD-EFFECT TRANSISTORS WITH DIFFERENT DRIVE STRENGTHS

(71) Applicant: International Business Machines Corporation, Armonk, NY (US)

(72) Inventors: Min Gyu Sung, Latham, NY (US); Julien Frougier, Albany, NY (US); Ruilong Xie, Niskayuna, NY (US); Liqiao Qin, Albany, NY (US)

(21) Appl. No.: 18/449,792

(22) Filed: Aug. 15, 2023

(51) Int. Cl. H10B 10/00

(52) U.S. Cl. CPC H10B 10/125

(57) ABSTRACT

Embodiments of the invention include a semiconductor structure having a first transistor having first nanosheets as first channel regions, a second transistor having second nanosheets as second channel regions, and a third transistor having third nanosheets as third channel regions. The first, second, and third nanosheets are formed of nanosheet material, where the first nanosheets are fewer in number than the second nanosheets. The semiconductor structure includes first end portions formed of the nanosheet material between first inner spacers in the first transistor. The first end portions are opposite one another and discontinuous in the first transistor.

### BACKGROUND

The present invention generally relates to fabrication methods and resulting structures for integrated circuits (ICs), and more specifically, to fabrication methods and resulting structures of nanosheet field-effect transistors with different drive strengths.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products of the future is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

Transistors in SRAM devices do not need to be driven the same. It would be beneficial to provide SRAM devices with different drive strengths.

### SUMMARY

Embodiments of the present invention are directed to providing static random access memory (SRAM) formation for nanosheet field-effect transistors with different drive strengths that provide better performance. A non-limiting method of forming a semiconductor structure includes providing a first transistor having first nanosheets as first channel regions, a second transistor having second nanosheets as second channel regions, and a third transistor having third nanosheets as third channel regions, the first, second, and third nanosheets being formed of nanosheet material, where the first nanosheets are fewer in number than the second nanosheets. The method includes providing first end portions formed of the nanosheet material between first inner spacers in the first transistor, the first end portions being opposite one another and discontinuous in the first transistor.

This can provide an improvement over known methods for forming SRAM devices by providing nanosheet FETs with different current drive strengths. The nanosheet FETs forming the pull down transistors, pass gate transistors, and pull up transistors have a different number of nanosheets forming the channel regions. Accordingly, the pull down transistors can have a strong current drive strength. The pass gate transistors can have a medium current drive strength. The pull up transistors can have a low or weak current drive strength. Further, by using nanosheet FETs having a different number of nanosheets according to the desired drive current, this reduces the cell area penalty compared to fin type transistors because the modifications are made in the vertical direction.

In addition to one or more of the features described above or below, additional features include the second nanosheets are fewer in number than the third nanosheets. This advantageously provides a different drive current for the nanosheet FETs.

In addition to one or more of the features described above or below, additional features include the first end portions are adjacent to epitaxial source/drain regions. This advantageously supports forming the epitaxial source/drain regions the same (e.g., at the same time, with the same height, with the same dimensions, etc.) for the pull down transistors, the pass gate transistors, and the pull up transistors.

In addition to one or more of the features described above or below, additional features include second end portions are formed of the nanosheet material between second inner spacers in the second transistor, the second end portions being opposite one another and discontinuous in the second transistor. This advantageously supports forming the epitaxial source/drain regions the same (e.g., at the same time, with the same height, with the same dimensions, etc.) for the pull down transistors, the pass gate transistors, and the pull up transistors.

In addition to one or more of the features described above or below, additional features include the second end portions are adjacent to epitaxial source/drain regions and fewer in number than the first end portions. This advantageously supports forming the epitaxial source/drain regions the same (e.g., at the same time, with the same height, with the same dimensions, etc.) for the pull down transistors, the pass gate transistors, and the pull up transistors. This advantageously provides a different drive current for the nanosheet FETs.

In addition to one or more of the features described above or below, additional features include epitaxial source/drain regions are substantially identical in the first, second, and third transistors. This advantageously supports forming the epitaxial source/drain regions the same (e.g., at the same time, with the same height, with the same dimensions, etc.) for the pull down transistors, the pass gate transistors, and the pull up transistors.

In addition to one or more of the features described above or below, additional features include the first, second, and third transistors are formed to utilize different electrical current drive strengths. This advantageously provides a different drive current for the nanosheet FETs.

According to one or more embodiments, a non-limiting method of forming a semiconductor structure includes providing a first transistor having first nanosheets as first channel regions, a second transistor having second nanosheets as second channel regions, and a third transistor having third nanosheets as third channel regions, the first, second, and third nanosheets being formed of nanosheet material. The method includes reducing an original thickness of the first channel regions of the first nanosheets in order to form narrowed first nanosheets with a first reduced thickness and form first end portions with the original thickness of the first nanosheets, a continuous piece of the nanosheet material in the first transistor forming the first end portions and the narrowed first nanosheets.

This can provide an improvement over known methods for forming SRAM devices by providing nanosheet FETs with different current drive strengths. The nanosheet FETs forming the pull down transistors, pass gate transistors, and pull up transistors have a different thickness for the nanosheets forming the channel regions. Accordingly, the pull down transistors can have a strong current drive strength. The pass gate transistors can have a medium current drive strength. The pull up transistors can have a low or weak current drive strength. Further, by using nanosheet FETs having different thicknesses for their nanosheets according to the desired drive current, this reduces the cell area penalty compared to fin type transistors because the modifications are made in the vertical direction.

In addition to one or more of the features described above or below, additional features include the first end portions are adjacent to epitaxial source/drain regions. This advantageously supports forming the epitaxial source/drain regions the same (e.g., at the same time, with the same height, with the same dimensions, etc.) for the pull down transistors, the pass gate transistors, and the pull up transistors.

In addition to one or more of the features described above or below, additional features include reducing the original thickness of the second channel regions of the second nanosheets in order to form narrowed second nanosheets with a second reduced thickness and form second end portions with the original thickness of the second nanosheets. This advantageously provides a different drive current for the nanosheet FETs.

In addition to one or more of the features described above or below, additional features include the second end portions are adjacent to epitaxial source/drain regions. This advantageously supports forming the epitaxial source/drain regions the same (e.g., at the same time, with the same height, with the same dimensions, etc.) for the pull down transistors, the pass gate transistors, and the pull up transistors.

In addition to one or more of the features described above or below, additional features include the second transistor includes second channel regions having narrowed second nanosheets with a second reduced thickness, the second reduced thickness being greater than the first reduced thickness. This advantageously provides a different drive current for the nanosheet FETs.

In addition to one or more of the features described above or below, additional features include the third channel regions of the third nanosheets have the original thickness, the original thickness being greater than the first reduced thickness. This advantageously provides a different drive current for the nanosheet FETs.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A and 1B respectively depict a top view and cross-sectional view of a portion of an integrated circuit (IC) under-fabrication after fabrication operations according to one or more embodiments of the invention;

FIG. 1C depicts a schematic of an example static random access memory (SRAM) array that includes six-transistor (6T) SRAM cells with transistors requiring different drive currents for optimal performance according to one or more embodiments of the invention;

FIGS. 2A and 2B respectively depict a top view and a cross-sectional view of a portion of an IC under-fabrication after fabrication operations according to one or more embodiments of the invention;

FIGS. 3A and 3B respectively depict a top view and a cross-sectional view of a portion of an IC under-fabrication after fabrication operations according to one or more embodiments of the invention;

FIGS. 4A and 4B respectively depict a top view and a cross-sectional view of a portion of an IC under-fabrication after fabrication operations according to one or more embodiments of the invention;

FIGS. 5A and 5B respectively depict a top view and a cross-sectional view of a portion of an IC under-fabrication after fabrication operations according to one or more embodiments of the invention;

FIGS. 6A, 6B, 6C, and 6D respectively depict a top view and cross-sectional views of a portion of an IC under-fabrication after fabrication operations according to one or more embodiments of the invention;

FIGS. 7A, 7B, 7C, and 7D respectively depict a top view and cross-sectional views of a portion of an IC under-fabrication after fabrication operations according to one or more embodiments of the invention;

FIGS. 8A, 8B, 8C, and 8D respectively depict a top view and cross-sectional views of a portion of an IC under-fabrication after fabrication operations according to one or more embodiments of the invention;

FIGS. 9A, 9B, 9C, and 9D respectively depict a top view and cross-sectional views of a portion of an IC under-fabrication after fabrication operations according to one or more embodiments of the invention;

FIGS. 10A, 10B, 10C, and 10D respectively depict a top view and cross-sectional views of a portion of an IC under-fabrication after fabrication operations according to one or more embodiments of the invention;

FIGS. 11A, 11B, 11C, and 11D respectively depict a top view and cross-sectional views of a portion of an IC under-fabrication after fabrication operations according to one or more embodiments of the invention;

FIGS. 12A, 12B, 12C, and 12D respectively depict a top view and cross-sectional views of a portion of an IC under-fabrication after fabrication operations according to one or more embodiments of the invention;

FIGS. 13A, 13B, 13C, and 13D respectively depict a top view and cross-sectional views of a portion of an IC under-fabrication after fabrication operations according to one or more embodiments of the invention;

FIGS. 14A, 14B, 14C, and 14D respectively depict a top view and cross-sectional views of a portion of an IC under-fabrication after fabrication operations according to one or more embodiments of the invention;

FIGS. 15A, 15B, 15C, and 15D respectively depict a top view and cross-sectional views of a portion of an IC under-fabrication after fabrication operations according to one or more embodiments of the invention;

FIGS. 16A, 16B, 16C, and 16D respectively depict a top view and cross-sectional views of a portion of an IC under-fabrication after fabrication operations according to one or more embodiments of the invention;

FIGS. 17A, 17B, 17C, and 17D respectively depict a top view and cross-sectional views of a portion of an IC under-fabrication after fabrication operations according to one or more embodiments of the invention;

FIGS. 18A, 18B, 18C, and 18D respectively depict a top view and cross-sectional views of a portion of an IC under-fabrication after fabrication operations according to one or more embodiments of the invention;

FIGS. 19A, 19B, 19C, and 19D respectively depict a top view and cross-sectional views of a portion of an IC under-fabrication after fabrication operations according to one or more embodiments of the invention;

FIGS. 20A, 20B, 20C, and 20D respectively depict a top view and cross-sectional views of a portion of an IC under-fabrication after fabrication operations according to one or more embodiments of the invention;

FIGS. 21A, 21B, 21C, and 21D respectively depict a top view and cross-sectional views of a portion of an IC under-fabrication after fabrication operations according to one or more embodiments of the invention;

FIGS. 22A, 22B, 22C, and 22D respectively depict a top view and cross-sectional views of a portion of an IC under-fabrication after fabrication operations according to one or more embodiments of the invention;

FIGS. 23A, 23B, 23C, and 23D respectively depict a top view and cross-sectional views of a portion of an IC under-fabrication after fabrication operations according to one or more embodiments of the invention; and

FIGS. 24A, 24B, 24C, and 24D respectively depict a top view and cross-sectional views of a portion of an IC under-fabrication after fabrication operations according to one or more embodiments of the invention.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The nanowire or nanosheet MOSFET is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure. The nanowire/nanosheet MOSFET device mitigates the effects of short channels and reduces drain-induced barrier lowering.

The GAA nanosheet FET structures can provide superior electrostatics. In contrast to known Fin-type FET (FinFET) structures in which the fin element of the transistor extends “up” out of the transistor, nanosheet FET designs implement the fin as a silicon nanosheet/nanowire. In a known configuration of a GAA nanosheet FET, a relatively small FET footprint is provided by forming the channel region as a series of nanosheets (i.e., silicon nanowires). A known GAA configuration includes a source region, a drain region, and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized.

IC structures often incorporate multiple FETs. For optimal circuit performance, some of the FETs on the same chip may require a higher drive current as compared to others. The different drive currents can be achieved by forming the different FETs so that they have different effective channel widths. However, depending upon the design of the FETs, the techniques used to form FETs with different effective channel widths will vary. For example, in planar single gate FETs, different channel widths can be achieved by using planar semiconductor bodies with different widths in the different FETs. In non-planar multi-gate FETs, such as FinFETs or tri-gate FETs, different effective channel widths can be achieved by using different numbers of semiconductor fins within different FETs and/or by using semiconductor fins having different heights within the different FETs. In typical designs attempting to provide different drive currents, there is a cell area penalty because more area on the chip is required to have differences between the FETs.

One or more embodiments provide fabrication methods and resulting structures for static random access memory (SRAM) formation for nanosheet field-effect transistors with different drive strengths that provide better performance. One or more embodiments provide an SRAM device that includes nanosheet FETs with a varied number of semiconductor nanosheets, thereby achieving different drive currents or strengths. The SRAM device can have one or more nanosheet FETs with a high drive current resulting from having the highest number of semiconductor nanosheets, one or more nanosheet FETs with a medium drive current resulting from having a medium number of semiconductor nanosheets, and one or more nanosheet FETs with a low or weak drive current resulting from having the lowest/fewest number of semiconductor nanosheets.

Further, one or more embodiments provide an SRAM device that includes nanosheet FETs with a varied thickness or height for the semiconductor nanosheets, thereby achieving different drive currents or strengths. The SRAM device can have one or more nanosheet FETs with a high drive current resulting from having the thickest semiconductor nanosheets, one or more nanosheet FETs with a medium drive current resulting from having a medium thickness for semiconductor nanosheets, and one or more nanosheet FETs with a low or weak drive current resulting from having the thinnest semiconductor nanosheets.

There are various technical benefits and solutions, according to one or more embodiments. One or more embodiments provide high performance SRAM device without a cell area penalty. In contrast to FinFETs, the semiconductor nanosheets in the nanosheet FETs are modified vertically in the same space normally utilized to form the nanosheet FET. Accordingly, there is no cell area penalty, while still providing different drive current strengths for the SRAM device.

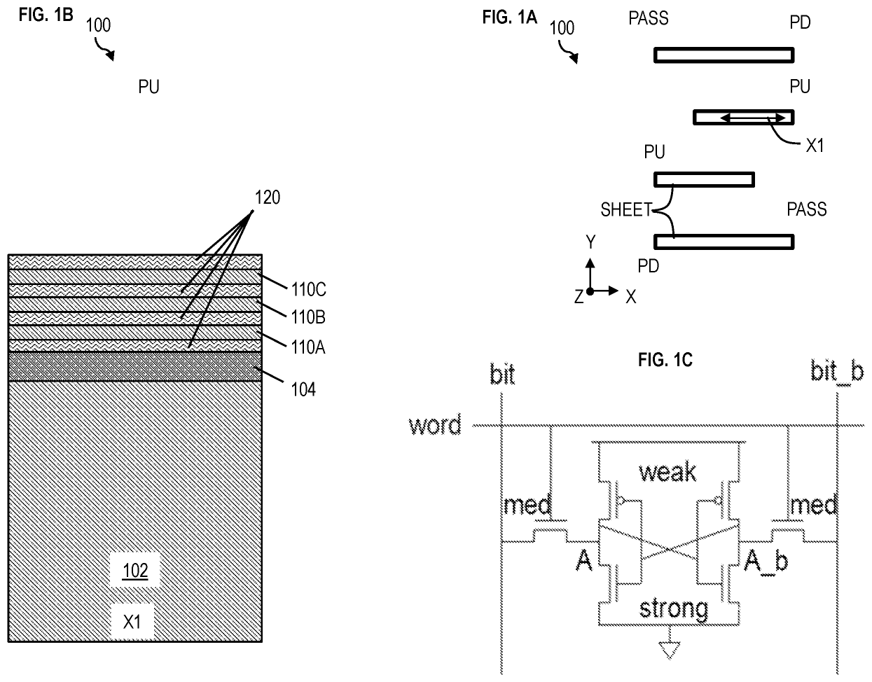

Turning now to a more detailed description of aspects of the present invention, FIG. 1A depicts a top view of a simplified illustration of a portion of an integrated circuit (IC) 100 and FIG. 1B depicts a cross-sectional view taken along X1 of the IC 100. For ease of understanding, some layers may be omitted from the various top views so as not to obscure the figure and to view layers underneath. As such, the top view is intended to provide a simplified illustration and a general orientation. Standard semiconductor fabrication techniques can be utilized to fabricate IC 100 as understood by one of ordinary skill in the art. Any suitable lithography processes including deposition techniques and etching techniques can be utilized herein.

For purposes of illustration, FIG. 1C is a schematic of a static random access memory (SRAM) array that includes six-transistor (6T) SRAM cells with transistors requiring different drive currents for optimal performance. An SRAM device includes two pull down (PD) transistors with high drive currents, two pass gate (PG) transistors with medium drive currents, and two pull up (PU) transistors with low/weak drive currents.

FIGS. 1A and 1B depict the IC 100 having a wafer where several fabrication processes have been performed. FIG. 1A illustrates fin patterning for one example cross-sectional view for a pull up transistor but applies to additional cross-sectional views for pull down and pass gate transistors (not shown at this time). A nanosheet stack is formed on a substrate 102. The wafer or substrate 102 may be formed of (pure) silicon. Other suitable materials can be utilized for the substrate 102. As seen in FIG. 1B, a bottom sacrificial layer 104 is formed on the substrate 102. The bottom sacrificial layer 104 is formed of silicon germanium (SiGe), where germanium has an atomic percent (%) of about 55% and silicon is the remainder. In one or more embodiments, the atomic percent of germanium can range from about 50-60% while silicon is the remainder in the bottom sacrificial layer 104. A nanosheet stack of semiconductor layers 110A, 110B, and 110C is formed with sacrificial layers 120 formed in between, and a sacrificial layer 120 formed on top. The semiconductor layers 110A, 110B, and 110C can generally be referred to as semiconductor layers 110 and may include substantially pure silicon. The semiconductor layers 110 will become the channel regions for the nanosheet FET device. The semiconductor layers 110 are nanosheets. Nanosheets can have a thickness of, for example, 5 nanometers. The thickness of a nanosheet can range from about 5-10 nm, and other ranges are possible. The sacrificial layers 120 are formed of silicon germanium (SiGe), where germanium has an atomic percent (%) of about 20% and silicon is the remainder. In one or more embodiments, the atomic percent of germanium can range from about 15-25% while silicon is the remainder in the sacrificial layer 120.

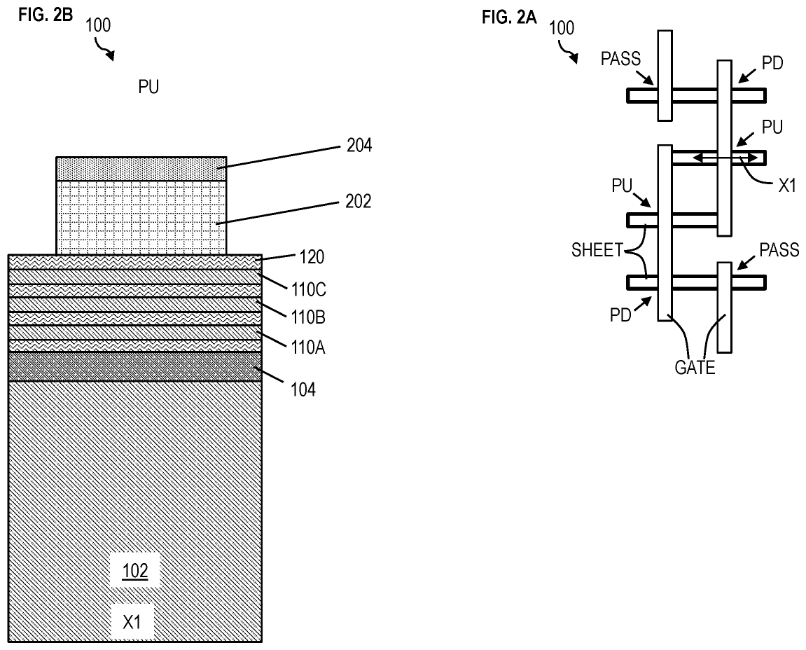

FIGS. 2A and 2B depict the IC 100 after dummy gate patterning. Sacrificial gate material is formed on the IC 100 to be a dummy gate 202, and a hard mask layer 204 is formed on top of the sacrificial gate material. The hard mask layer 204 is patterned, and the patterned hard mask layer 204 is utilized to etch the sacrificial gate material into the dummy gate 202. Example materials of the dummy gate 202 can include amorphous silicon, polycrystalline silicon, etc. Example materials of the hard mask layer 204 can include nitride materials such as silicon nitride.

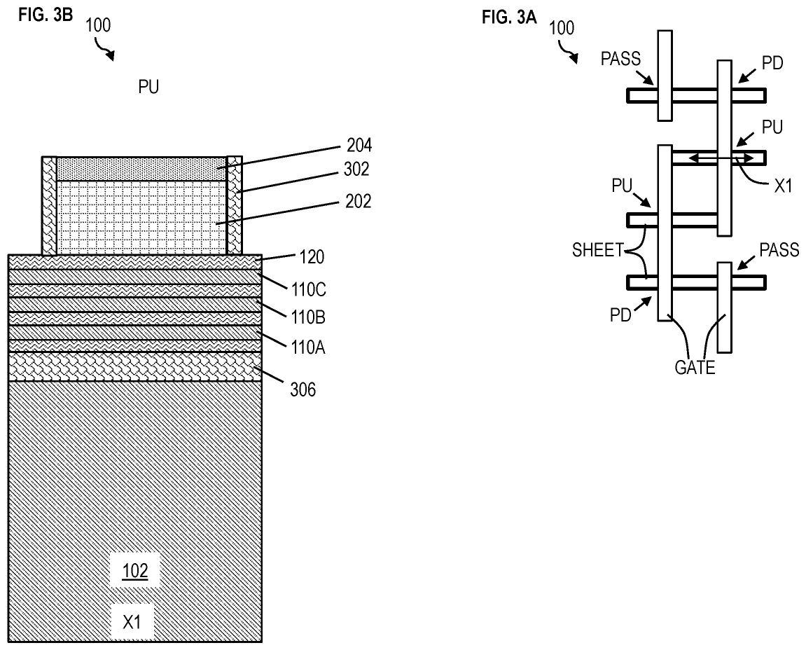

FIGS. 3A and 3B depict the IC 100 after gate spacer deposition and etching. The bottom sacrificial layer 104 is selectively removed, leaving an empty cavity. It is noted that the bottom sacrificial layer 104 has the highest atomic percent of germanium in the silicon germanium material, and the bottom sacrificial layer 104 can be selectively etched versus the sacrificial layers 120 and the semiconductor layers 110. After that, gate spacer material is deposited at the sides of the dummy gate 202 as well as into the empty cavity left after removal of the bottom sacrificial layer 104. Etching is performed to form gate spacers 302 and bottom dielectric interface layer 306. Example materials of the gate spacer 302 and the bottom dielectric interface layer 306 can include nitride materials, such as SiN, SiBCN, SiOCN, SiOC, etc.

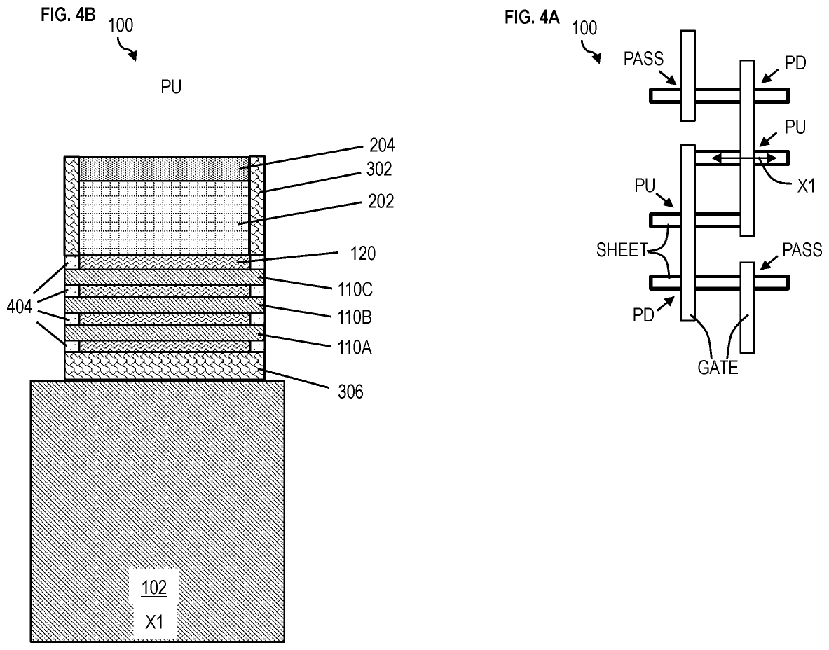

FIGS. 4A and 4B depict the IC 100 after nanosheet pulldown and inner space formation. Directional etching is performed while using the hard mask layer 204 and the gate spacers 302 as a protective mask, in order to trim the nanosheet stack. As a result of the etching, the unprotected portions of the semiconductor layers 110 and the sacrificial layers 120 are removed.

To form inner spacers 404, isotropic etching is performed to selectively remove end portions of the scarification layers 120 resulting in cavities at the ends. Inner spacer material is deposited to fill the cavities, and etching is performed to remove the excess spacer material, resulting in the inner spacers 404 on the ends of the sacrificial layers 120. Example materials of the inner spacers 404 can include nitrides, low-k dielectric materials, etc. Example materials of the inner spacers 404 may include SiBCN, SiOCN, SiN, SiOC, SiC, etc.

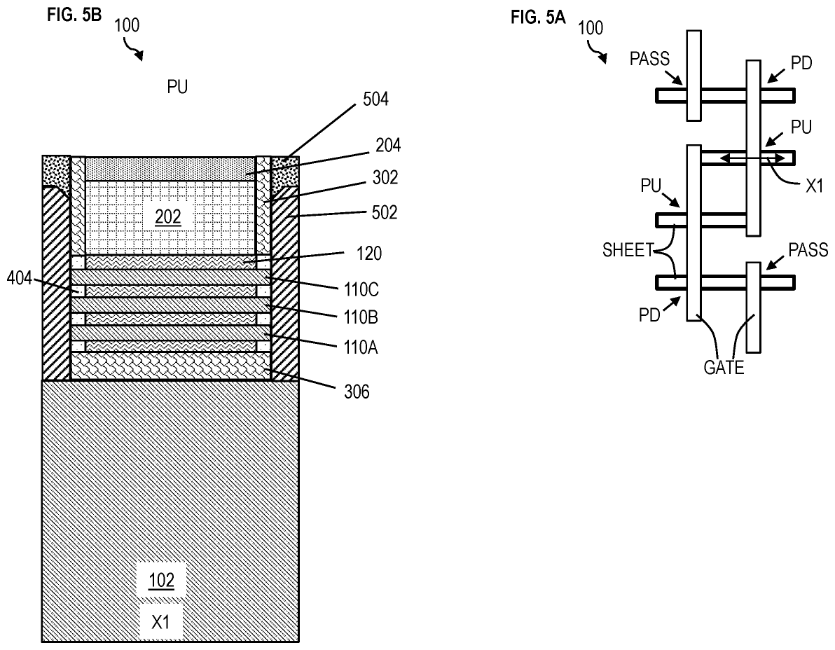

FIGS. 5A and 5B depict the IC 100 after source and drain epitaxial deposition and interlayer/intralayer dielectric formation. To form epitaxial source/drain regions 502, semiconductor material is deposited and epitaxially grown from the nanosheet semiconductor layers 110 and the substrate 102. The semiconductor material can be doped with n-type or p-type dopants according to whether an n-type or p-type transistor is being formed. Interlayer dielectric (ILD) material 504 is deposited. The ILD material 504 can be a low-k dielectric material, an ultra-low-k dielectric material, etc. The ILD material 504 can include SiO₂, or low-k and ultra-low-k dielectric materials with a k-value<4.

As discussed herein, fabrication operations have been discussed for an example nanosheet FET but the fabrication operations are currently performed and applied by analogy to the other nanosheet FETs in the SRAM device. Additional cross-sectional views will be presented below to aid in understanding.

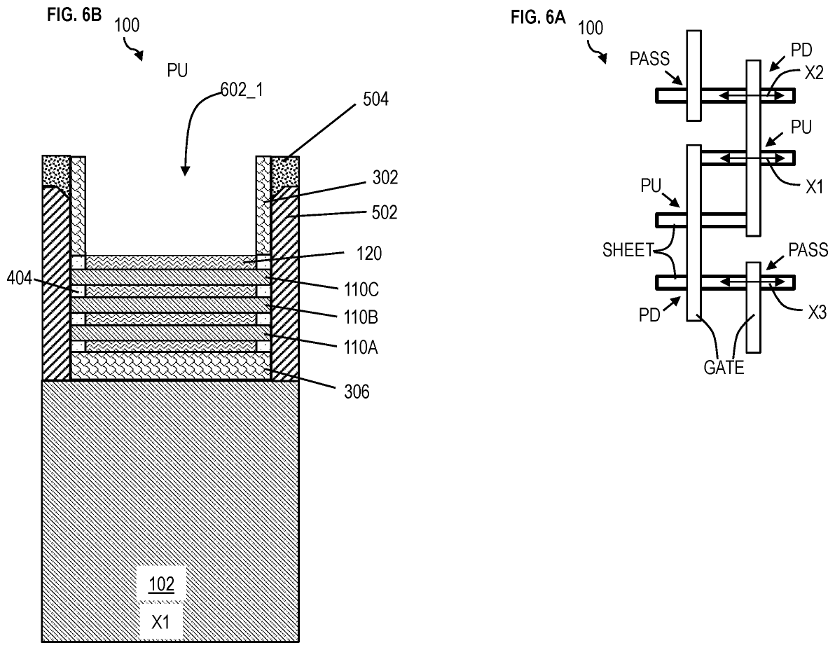

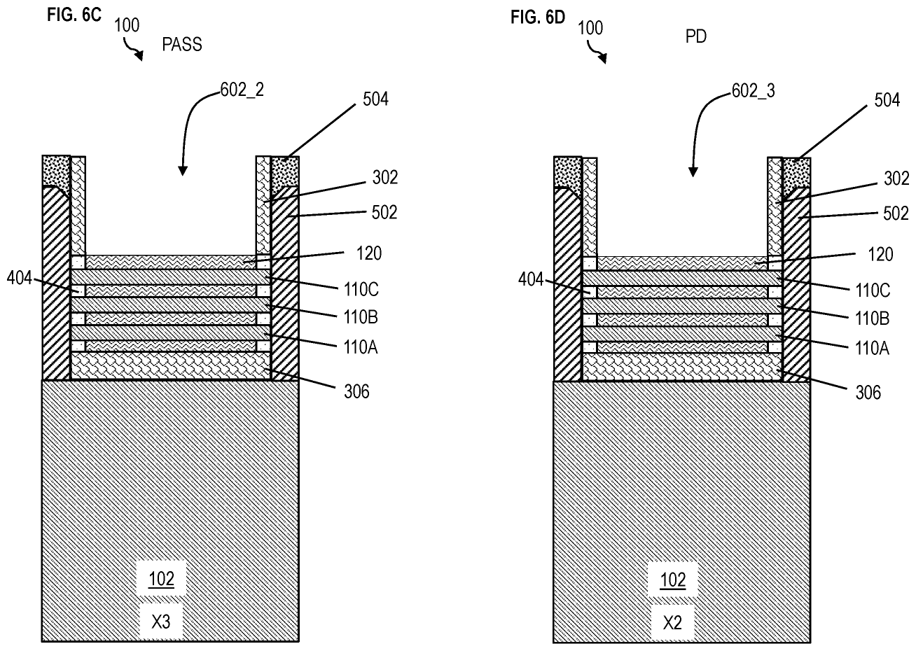

FIGS. 6A, 6B, 6C, and 6D depict the IC 100 after dummy gate removal. As noted herein, FIG. 6A is a top view of a simplified illustration of a portion of the IC 100, and FIG. 6B depicts a cross-sectional view taken along X1 of the IC 100. FIG. 6C depicts a cross-sectional view taken along X3 of the IC 100, and FIG. 6D depicts a cross-sectional view taken along X2 of the IC 100. FIGS. 6B, 6C, and 6D respectively depict cross-sectional views of a nanosheet pull up transistor, a nanosheet pass gate transistor, and a nanosheet pull down transistor. For example, the formation of the pull up transistor, the nanosheet pass gate transistor, and the nanosheet pull down transistor is similar with minor exceptions versus forming n-type and p-type transistors. The fabrication of FIGS. 6A, 6B, 6C, and 6D continues from the FIGS. 5A and 5B.

Etching is performed to remove the hardmask layer 204 and further etching is performed to remove the dummy gate 202. In one or more embodiments, a mask can be utilized during the etching to protect portions of the IC 100. The removal of the hardmask layer 204 and dummy gate 202 results in trenches 602_1, 602_2, and 602_3, exposing the top-most sacrificial layer 120.

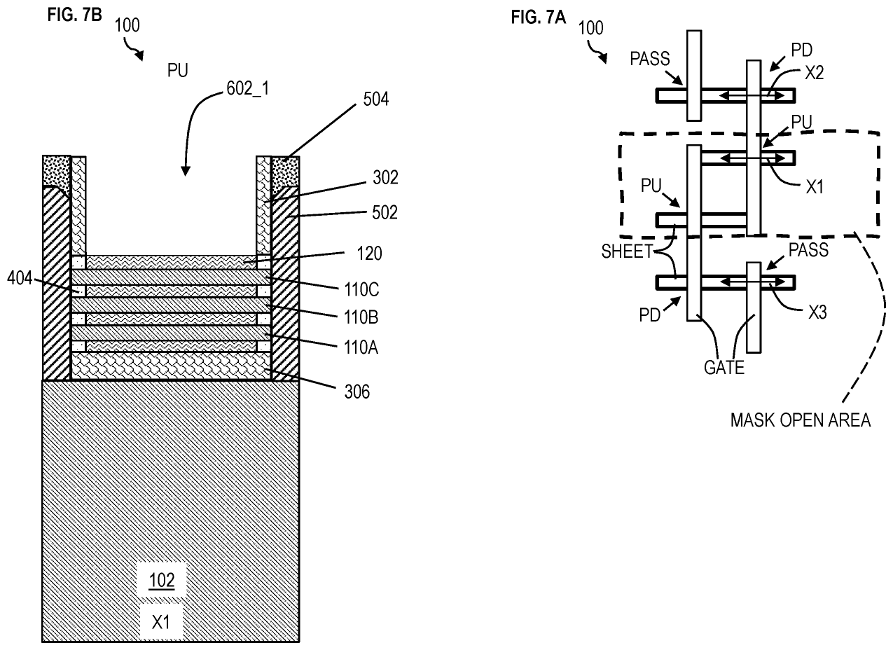

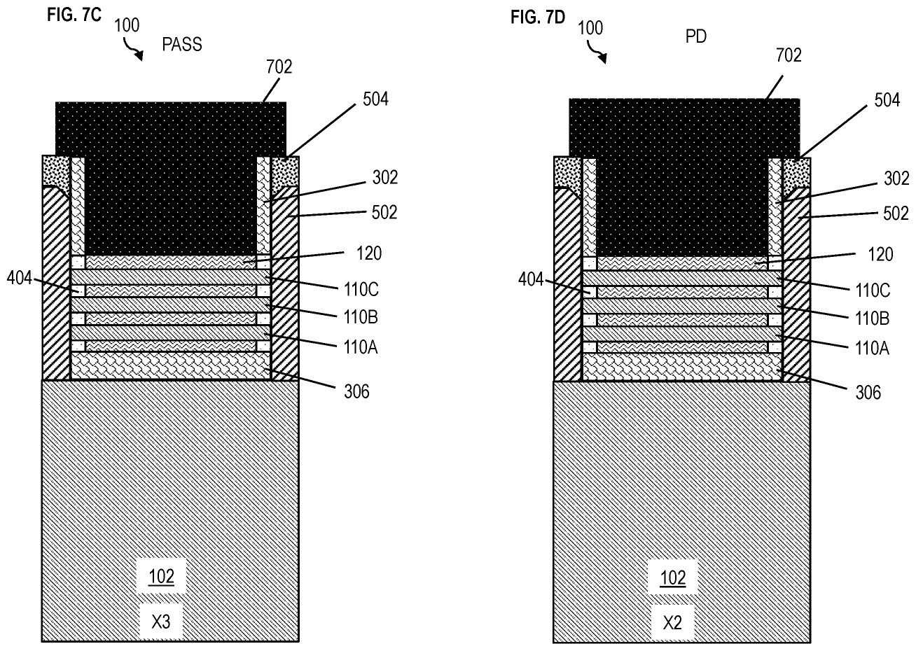

FIGS. 7A, 7B, 7C, and 7D depict the IC 100 after mask deposition. A mask layer 702 is deposited and etched. The mask layer 702 may be an organic patterning layer (OPL) and/or any suitable material or combination of materials. Lithography is performed to open up the mask layer 702 at the pull up transistors. The mask layer 702 is to be utilized to protect the pass gate and pull down transistors in subsequent fabrication steps.

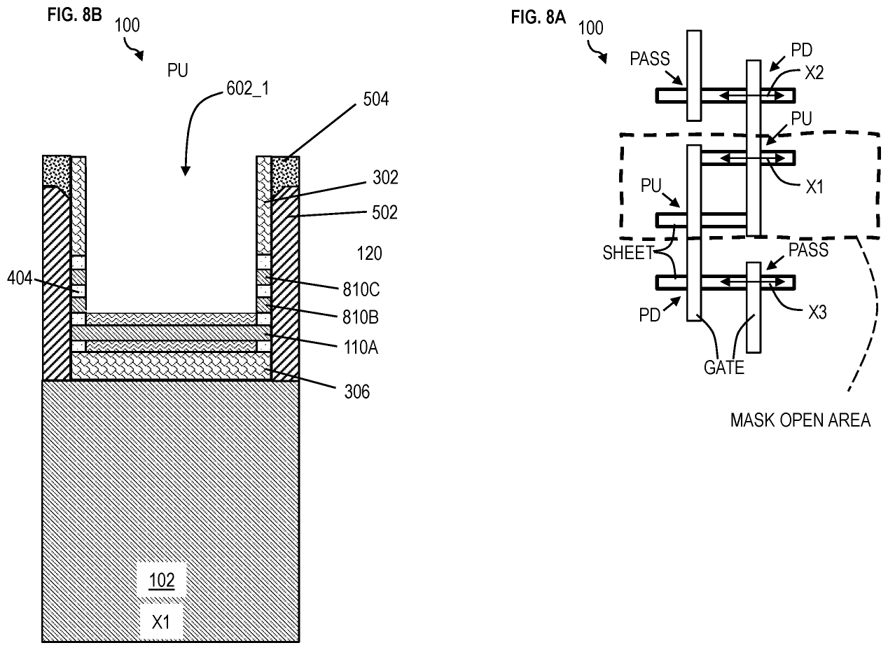

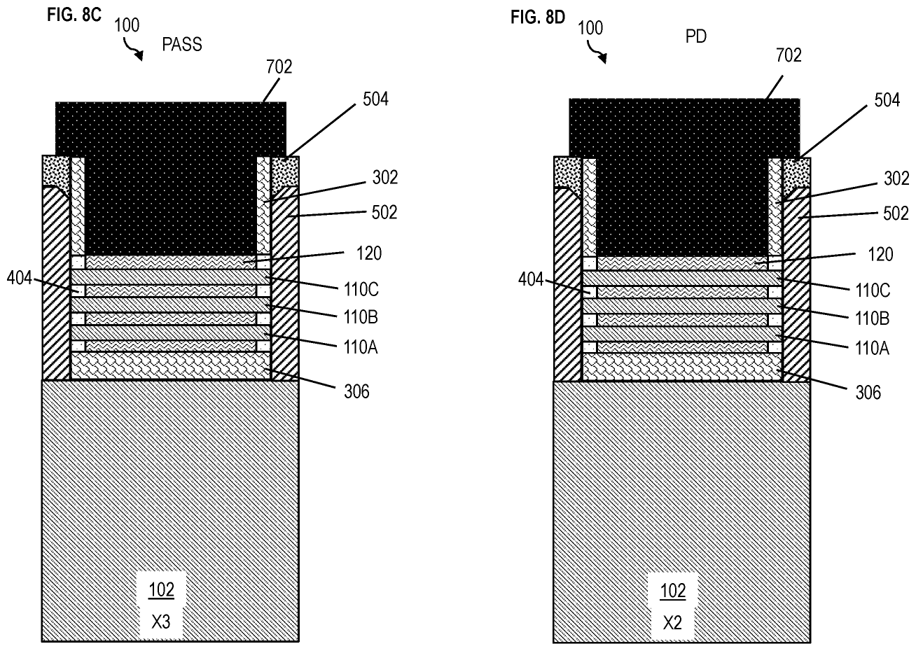

FIGS. 8A, 8B, 8C, and 8D depict the IC 100 after etching. While the pass gate and pull down transistors are protected, a reactive ion etch can be performed to remove four nanosheet layers, which are two sacrificial layers 120, semiconductor layer 110C, and semiconductor layer 110B, as seen in FIG. 8B. End portions 810B and 810C of the removed semiconductor layers 110B and 110C remain stacked underneath the inner spacers 404, as seen in FIG. 8B.

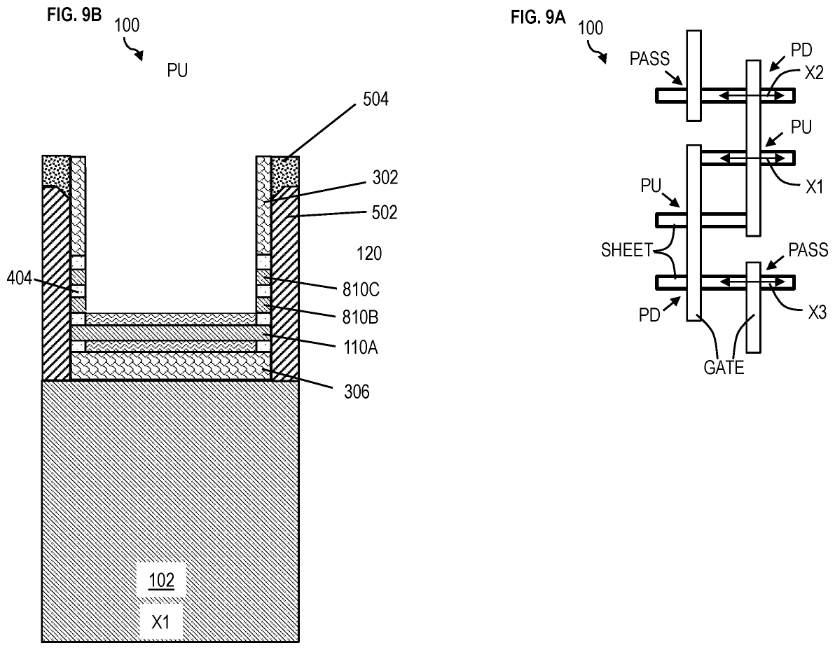

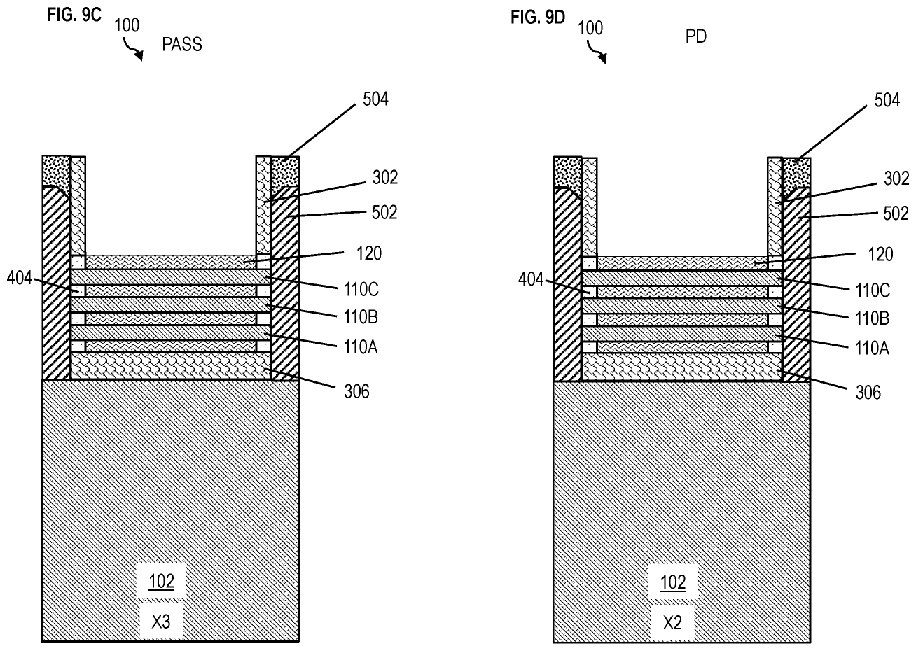

FIGS. 9A, 9B, 9C, and 9D depict the IC 100 after removal of the mask layer 702. The mask layer 702 can be removed, for example, by ashing the OPL.

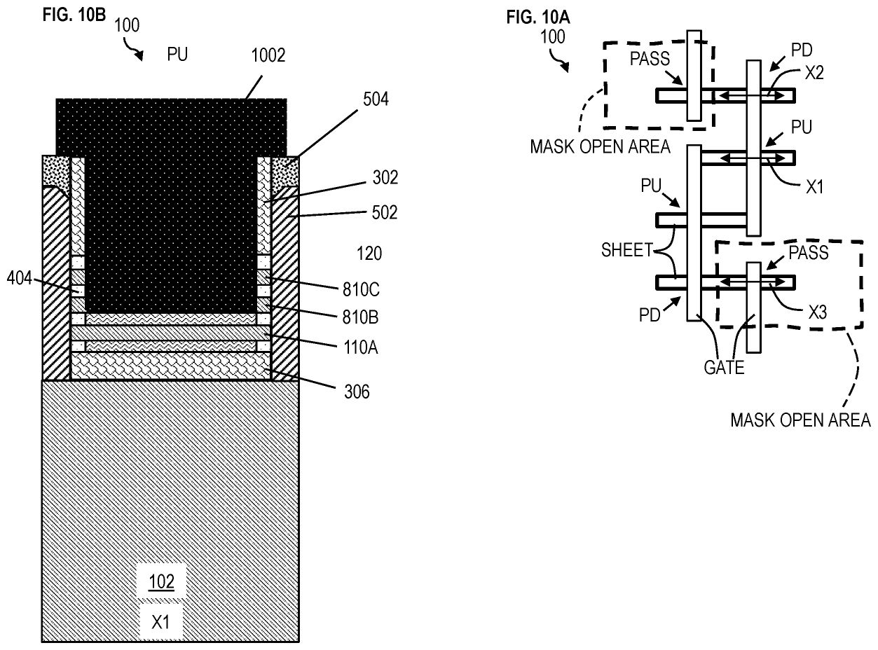

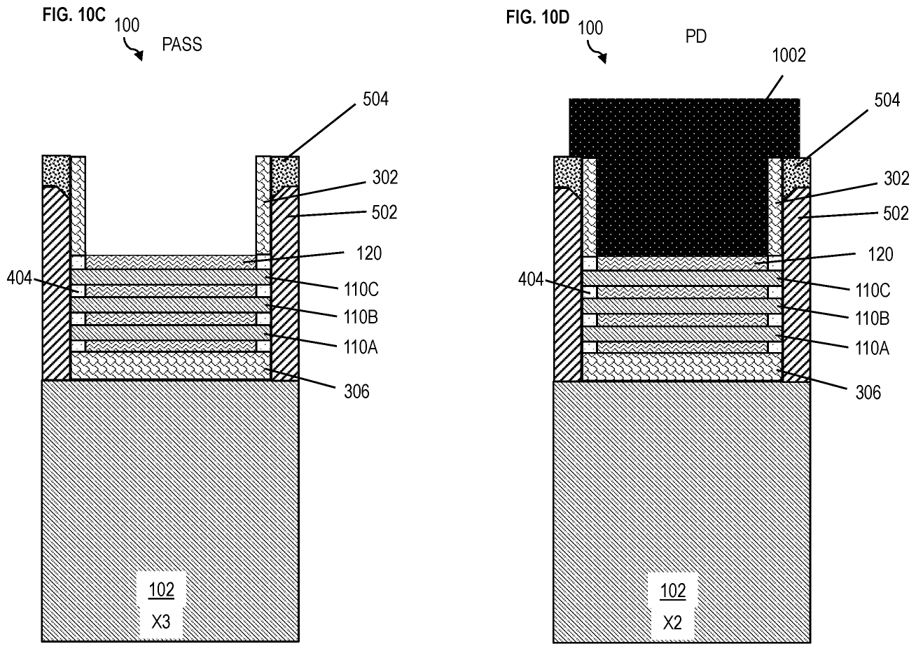

FIGS. 10A, 10B, 10C, and 10D depict the IC 100 after mask deposition. A mask layer 1002 is deposited and etched. The mask layer 1002 may be an OPL and/or any suitable material or combination of materials. Lithography is performed to open up the mask layer 1002 at the pass gate transistors, as depicted in FIG. 10C. The mask layer 1002 is utilized to protect the pull up and pull down transistors in subsequent fabrication steps.

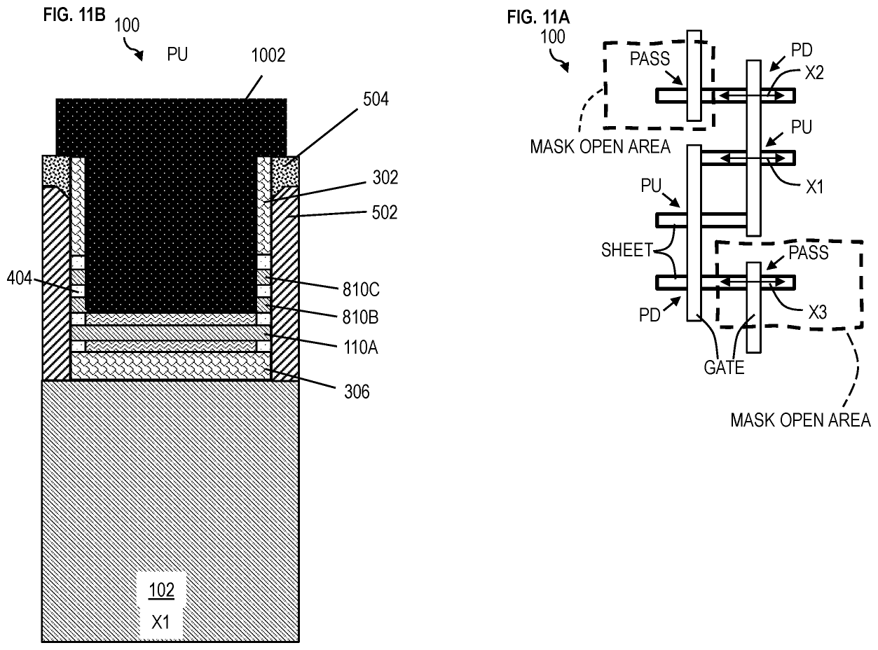

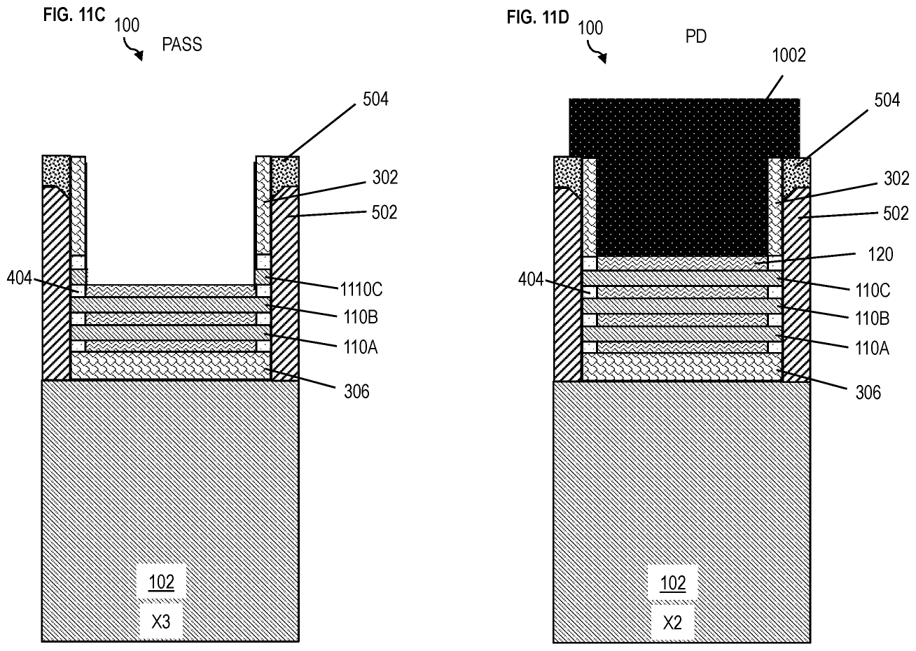

FIGS. 11A, 11B, 11C, and 11D depict the IC 100 after etching. While the pull up and pull down transistors are protected, a reactive ion etch can be performed to remove two nanosheet layers, which are one sacrificial layer 120 and one semiconductor layer 110C, as seen in FIG. 11C. End portions 1110C of the removed semiconductor layer 110C remain stacked underneath the inner spacers 404, as seen in FIG. 11C.

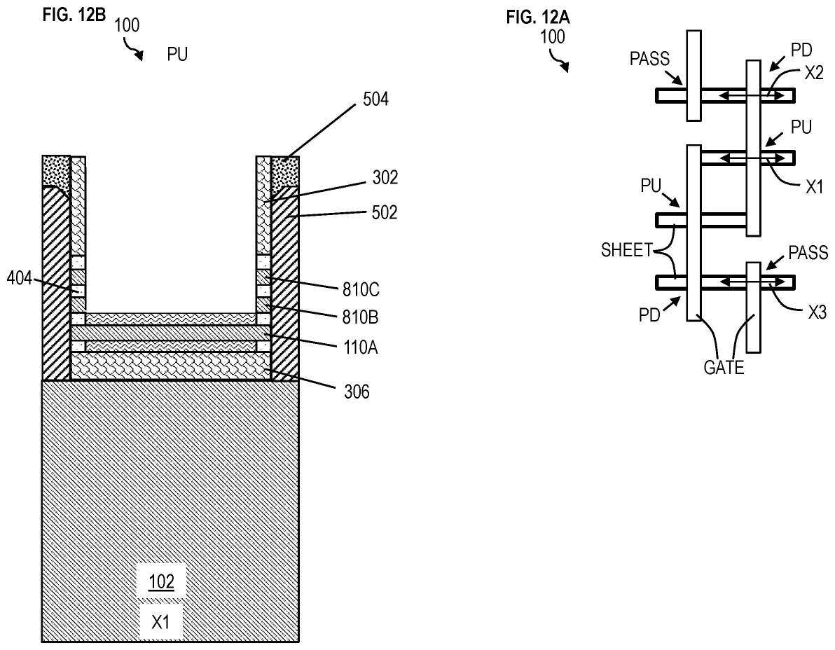

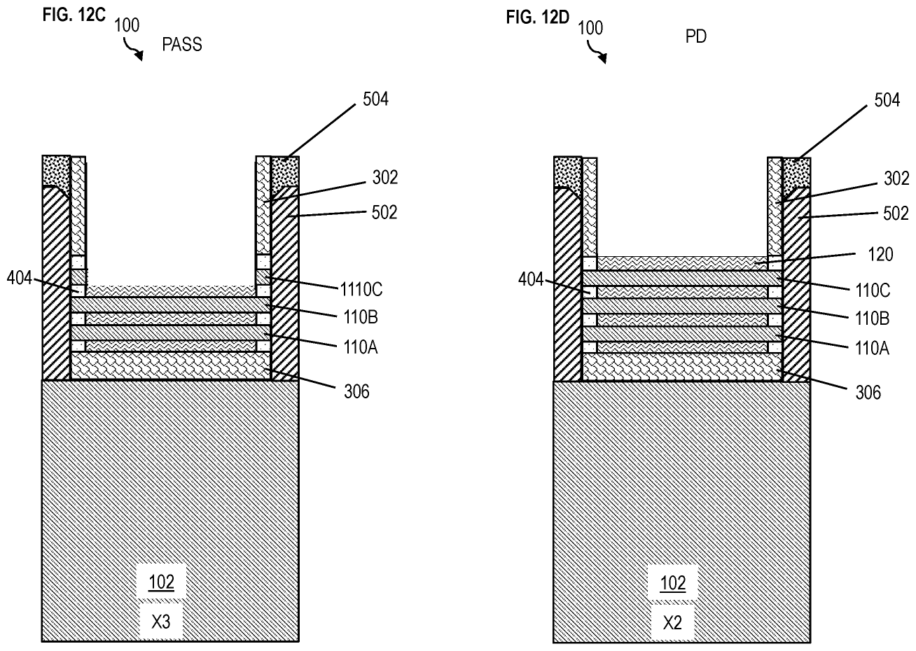

FIGS. 12A, 12B, 9C, and 9D depict the IC 100 after removal of the mask layer 1002. The mask layer 702 can be removed, for example, by ashing the OPL.

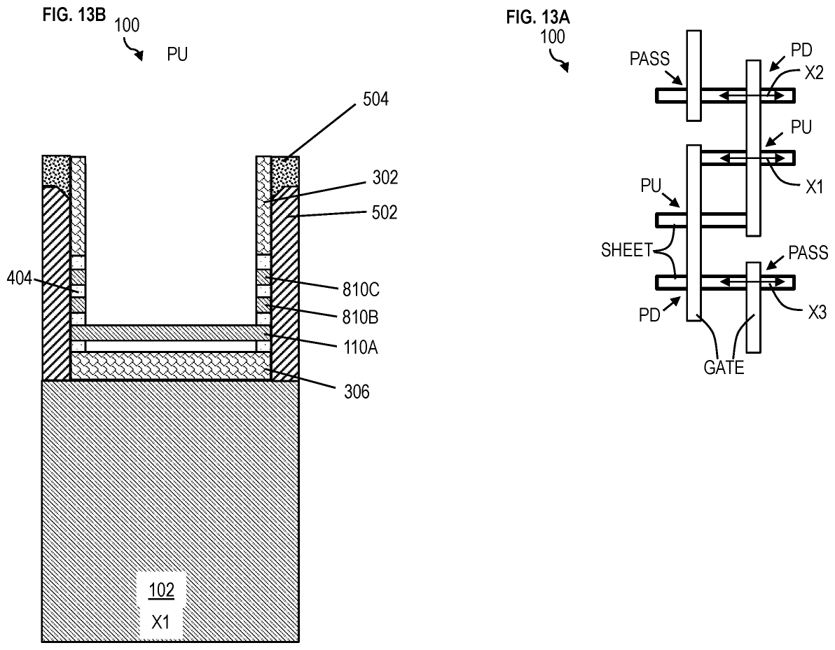

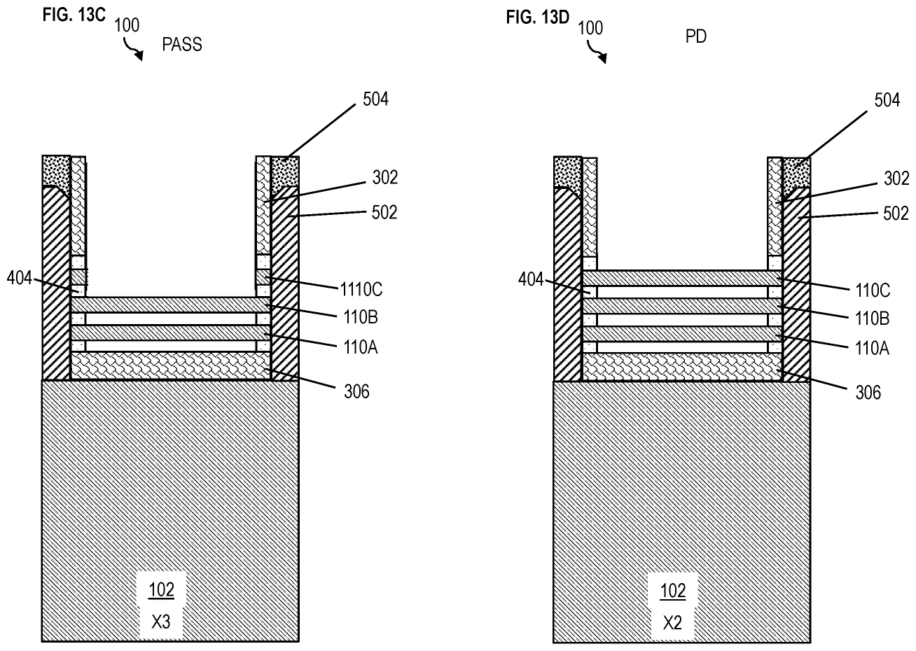

FIGS. 13A, 13B, 13C, and 13D depict the IC 100 after removal of the silicon germanium. Etching is performed to selectively remove the sacrificial layers 120. The etching results in one exposed nanosheet semiconductor layer 110A in the pull up transistor depicted in FIG. 13B, two exposed nanosheet semiconductor layers 110A and 110B in the pass gate transistor depicted in FIG. 13C, and three exposed nanosheet semiconductor layers 110A, 110B, and 110C depicted in FIG. 13D; accordingly, this provides three different drive current strengths in the final nanosheet FETs.

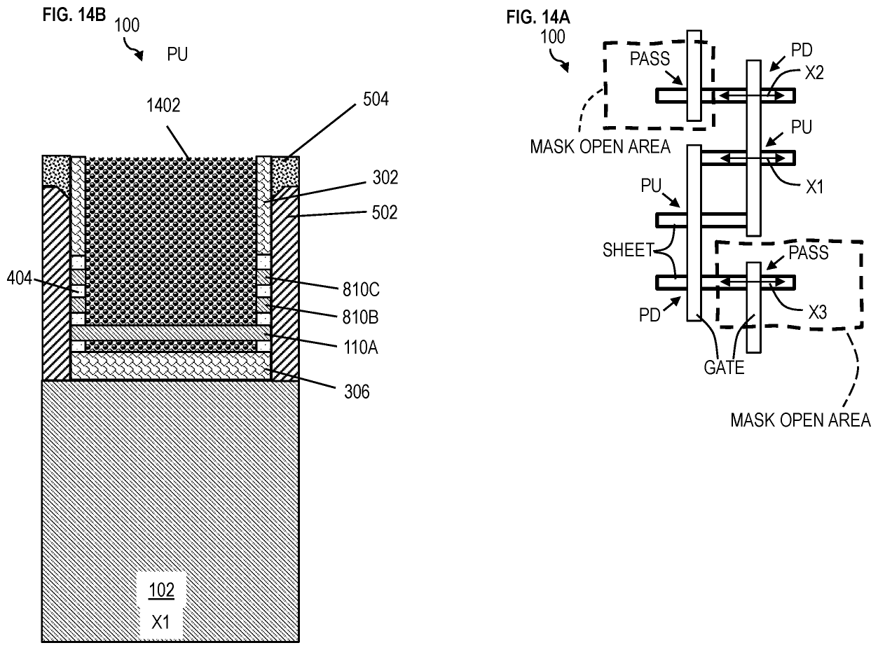

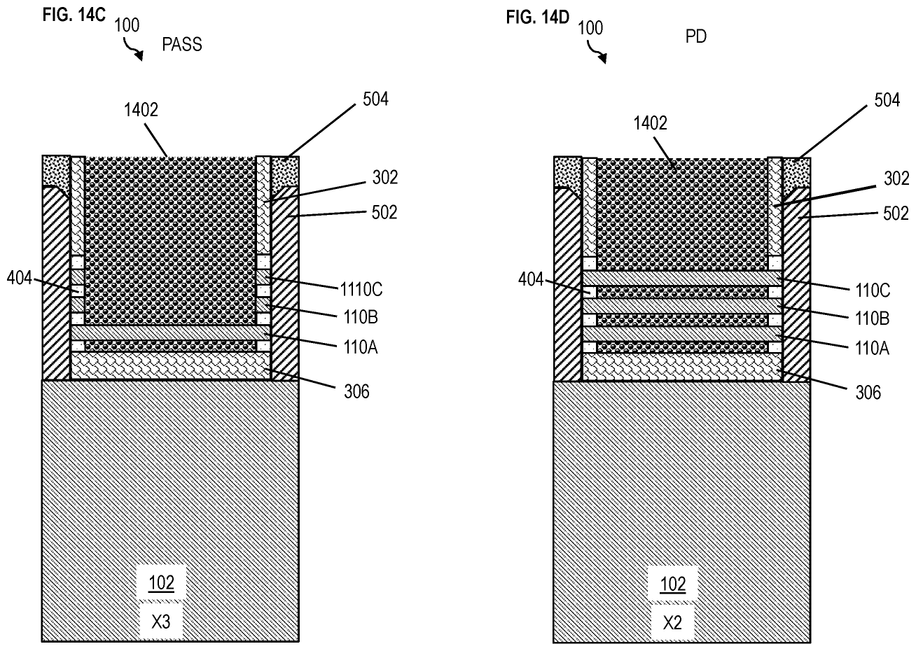

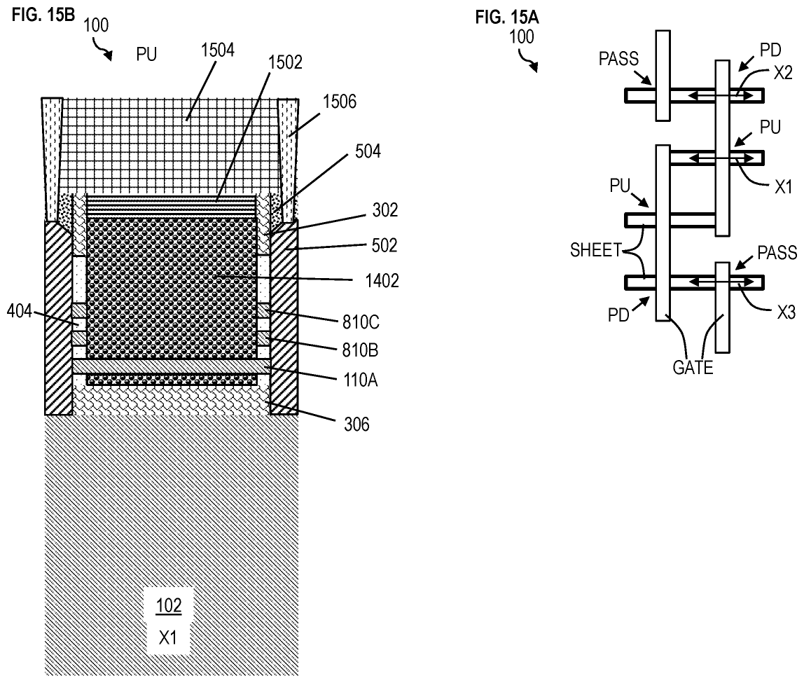

FIGS. 14A, 14B, 14C, and 14D depict the IC 100 after high-k material deposition and work function material deposition. Gate material 1402 is formed around the semiconductor layers 110. The gate material 1402 includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

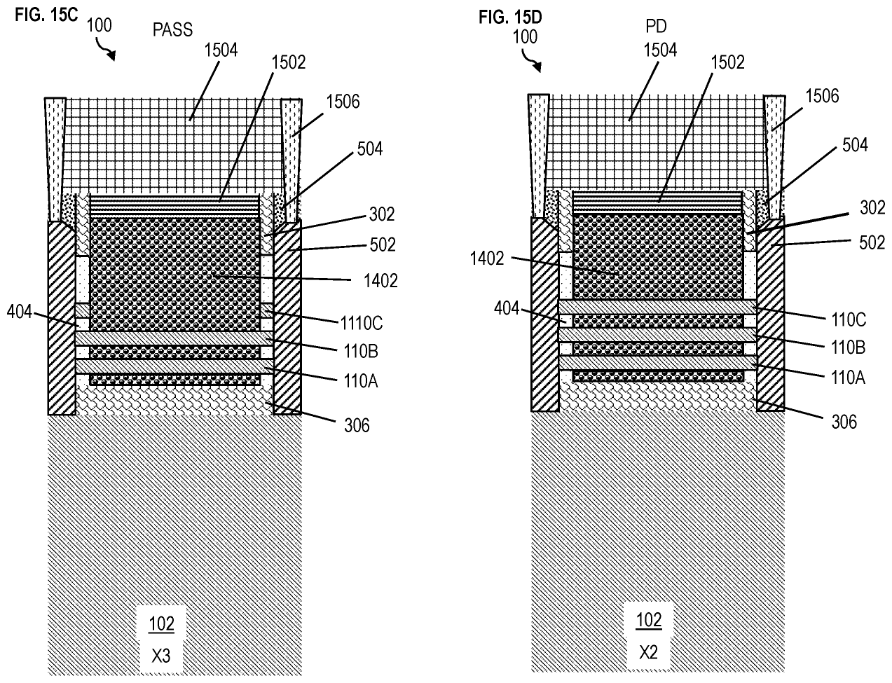

FIGS. 15A, 15B, 15C, and 15D depict the IC 100 after contact formation and ILD formation. The gate material 1402 is recessed, and a cap layer 1502 is formed on top of the gate material 1402. Example materials of the cap layer 1502 can include nitrides, such as, for example, SiN. Further ILD material 1504 is deposited, source/drain contact openings are patterned by conventional lithography, and then metal is deposited to fill the cavities thereby forming the metal contacts 1506. A portion of the metal contacts may include silicide, resulting from the interface of the metal material and semiconductor material. The metal contacts 1506 are source/drain contacts that are respectively connected to epitaxial source/drain regions 502.

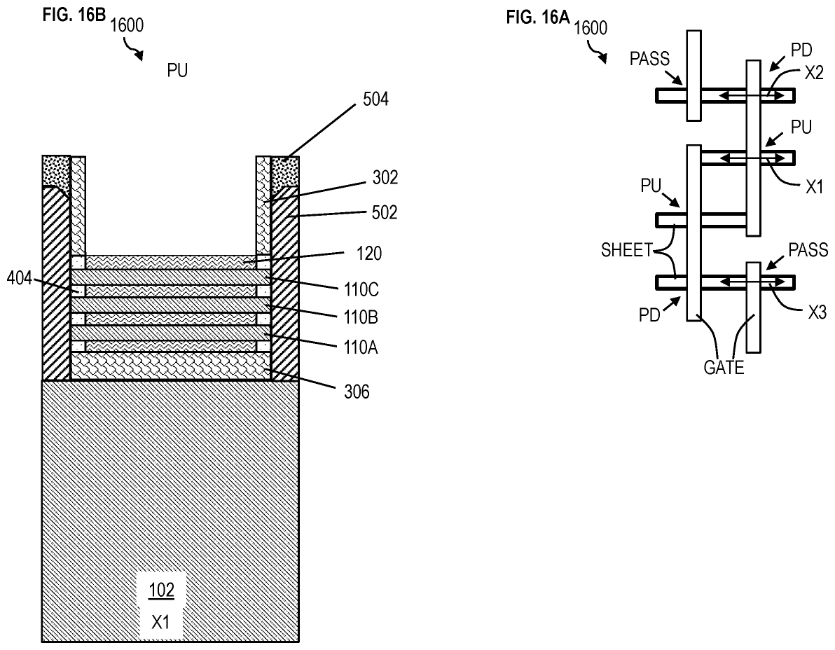

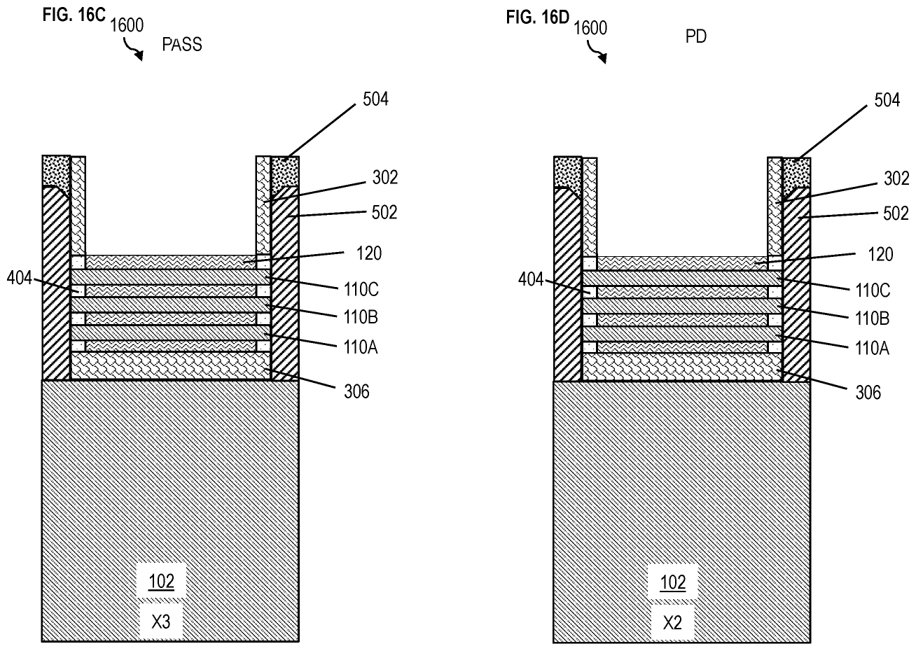

According to one or more embodiments, FIGS. 16-25 depict fabrication of a portion of an IC 1600 for an SRAM array that includes six-transistor (6T) SRAM cells with transistors requiring different drive currents for optimal performance. Continuing at FIGS. 6A, 6B, 6C, and 6D discussed herein, FIGS. 16A, 16B, 16C, and 16D depict the IC 1600 after dummy gate removal. FIG. 16B depicts a cross-sectional view taken along X1 of the IC 1600. FIG. 16C depicts a cross-sectional view taken along X3 of the IC 1600, and FIG. 16D depicts a cross-sectional view taken along X2 of the IC 1600. FIGS. 16B, 16C, and 16D respectively depict cross-sectional views of a nanosheet pull up transistor, a nanosheet pass gate transistor, and a nanosheet pull down transistor.

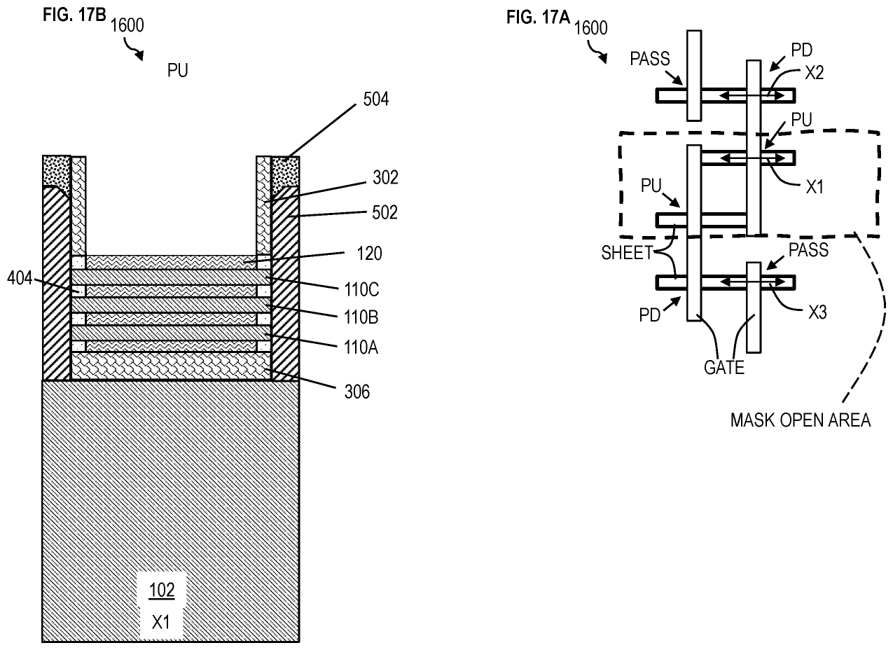

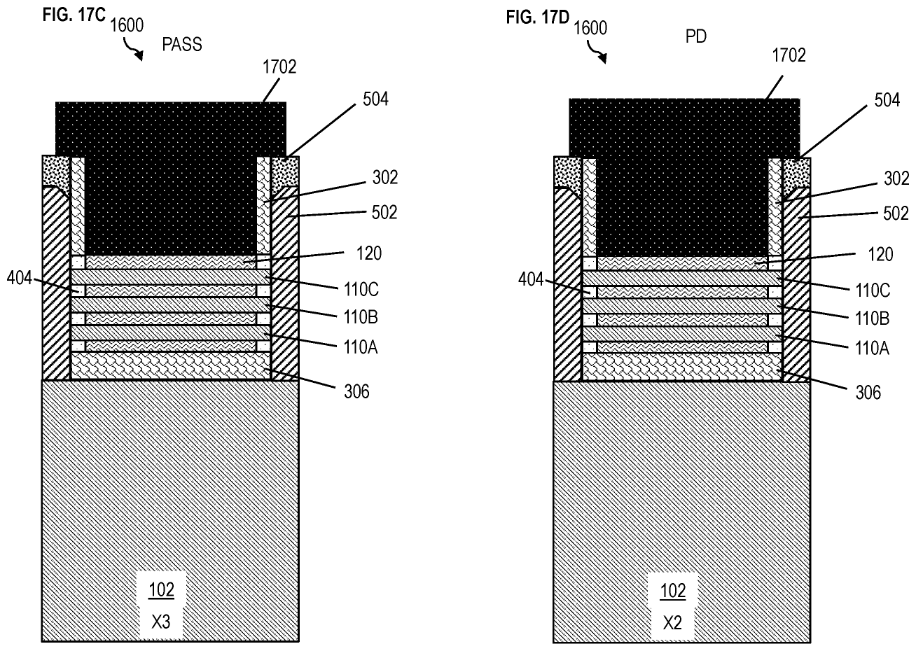

FIGS. 17A, 17B, 17C, and 17D depict the IC 1600 after mask deposition. A mask layer 1702 is deposited and etched. The mask layer 1702 may be OPL material and/or any suitable material or combination of materials. Lithography is performed to open up the mask layer 1702 at the pull up transistors. The mask layer 702 is utilized to protect the pass gate and pull down transistors in subsequent fabrication steps.

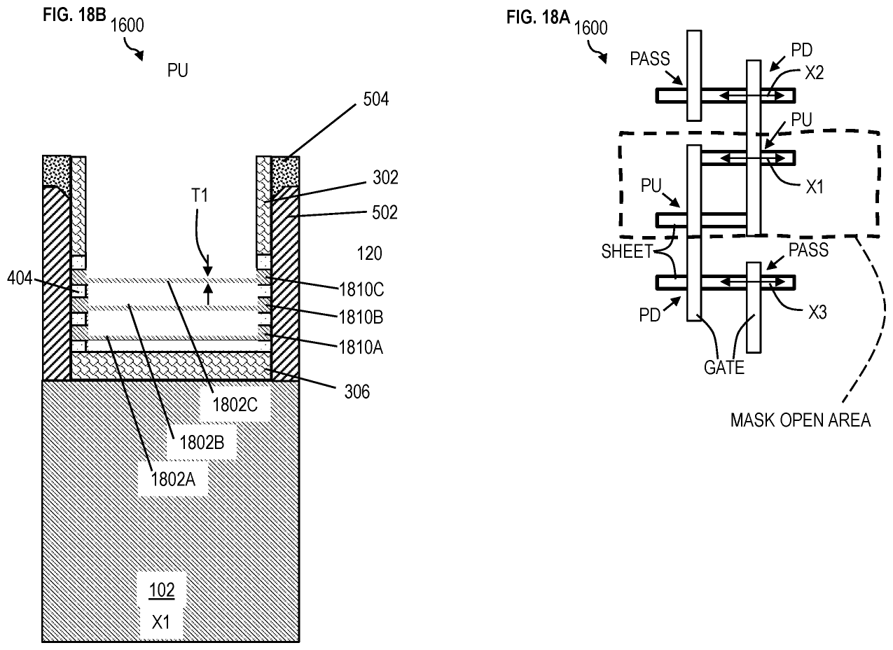

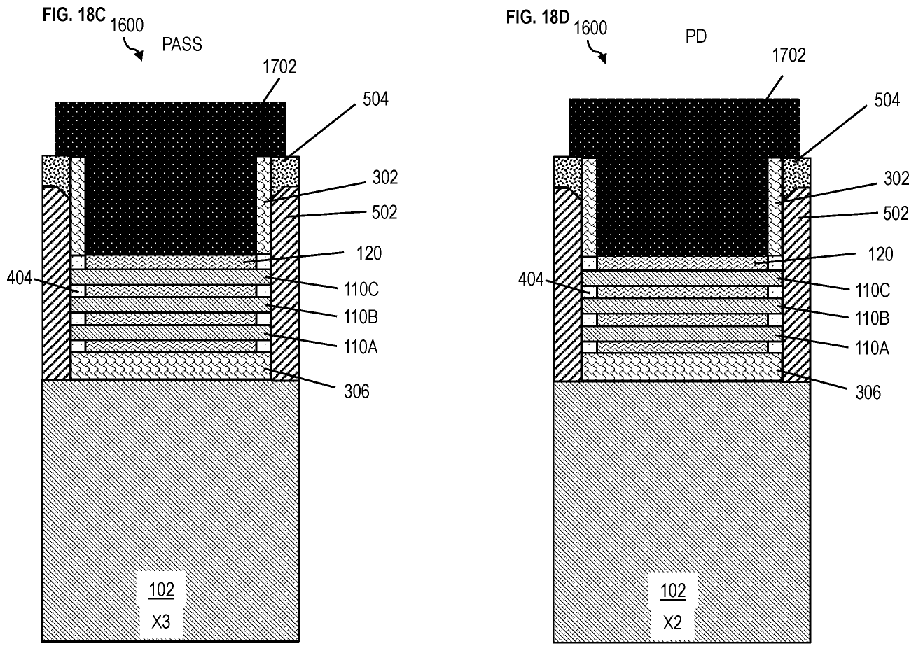

FIGS. 18A, 18B, 18C, and 18D depict the IC 1600 after channel release and silicon trimming. For the exposed sacrificial layers without the protective mask layer 1702, etching is performed to selectively etch the sacrificial layers 120 of the pull up transistors. An example etchant for the channel release can include HCl. Further etching is performed to respectively reduce the thickness of the semiconductor layers 110A. 110B, and 110C of the pull up transistors into narrowed semiconductor layers 1802A, 1802B, and 1802C, as seen in FIG. 18B. A wet or dry etchant can be utilized to trim the semiconductor layers 110A, 110B, and 110C. For precise control in etch amount of the trim, an atomic layer etch process can be used. As a result of reducing the thickness of the semiconductor layers 110A, 110B, and 110C to form the narrowed semiconductor layers 1802A, 1802B, and 1802C, end portions 1810A, 1810B, and 1810C are formed and remain underneath the inner spacers 404, as seen in FIG. 18B. The end portions 1810A, 1810B, and 1810C have the original thickness of the nanosheet semiconductor layers 110A, 110B, and 110C prior to trimming. The narrowed semiconductor layers 1802A, 1802B, and 1802C have a thickness T1 that is less than the original thickness of the nanosheet semiconductor layers 110A, 110B, and 110C.

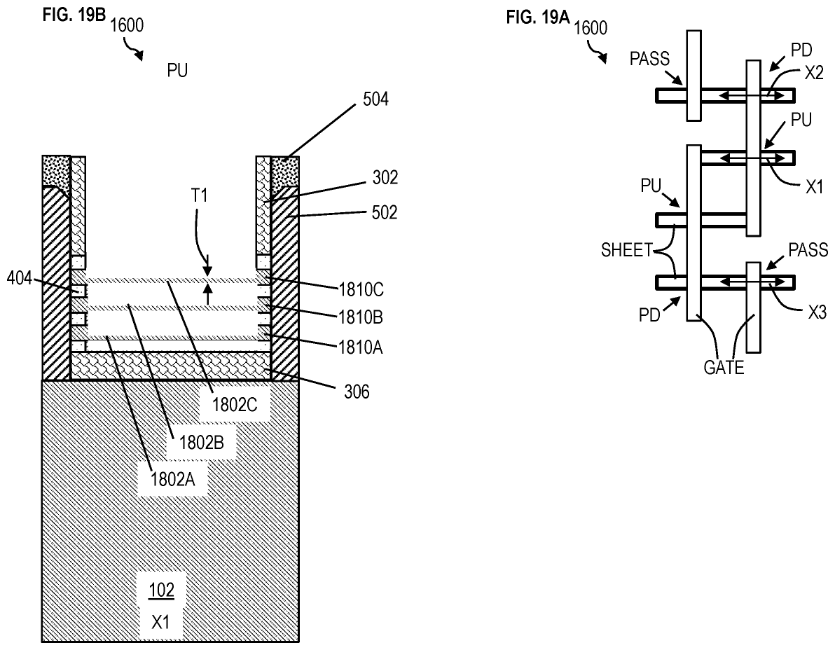

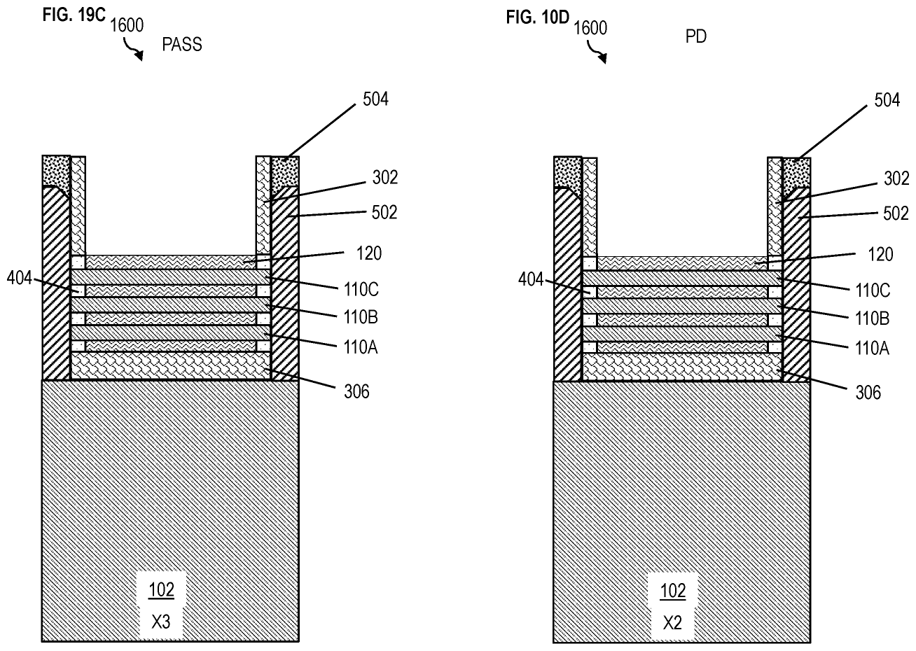

FIGS. 19A, 19B, 19C, and 19D depict the IC 1600 after removal of the mask layer 1702. The mask layer 1702 can be removed, for example, by ashing the OPL.

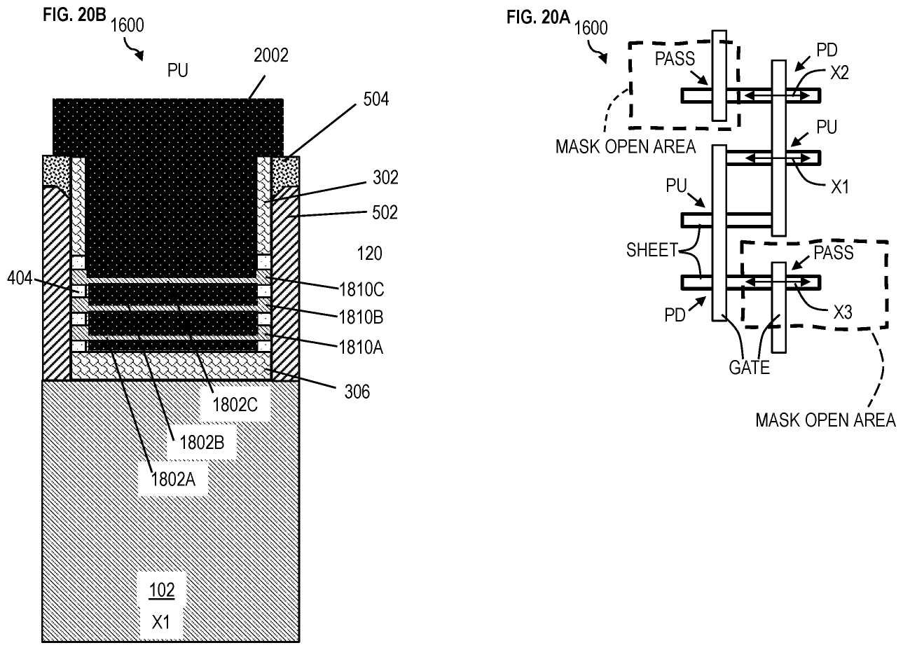

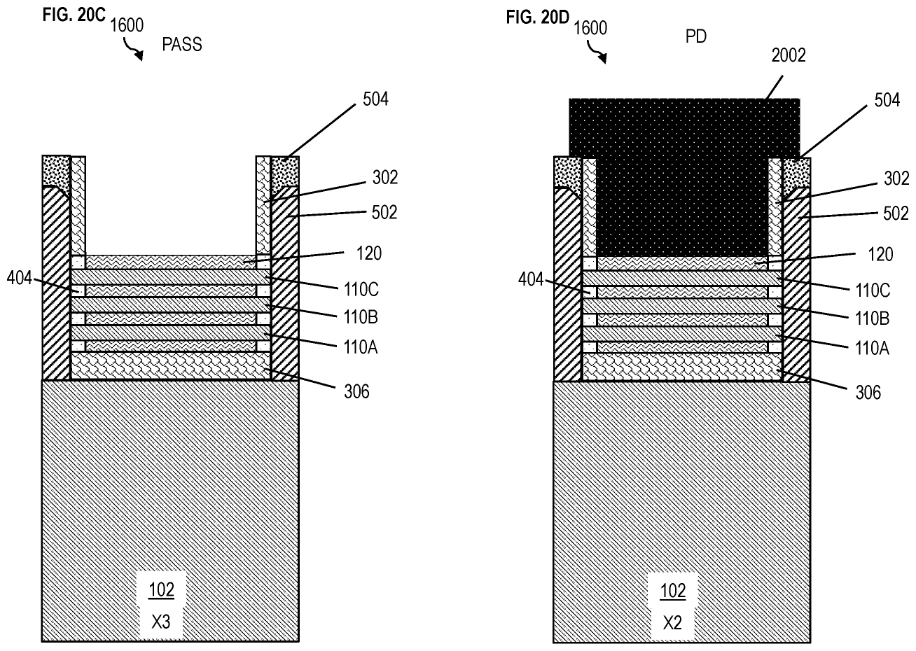

FIGS. 20A, 20B, 20C, and 20D depict the IC 1600 after mask deposition. A mask layer 2002 is deposited and etched. The mask layer 2002 may be OPL material and/or any suitable material or combination of materials. Lithography is performed to open up the mask layer 2002 at the pass gate transistors. The mask layer 2002 is utilized to protect the pull up and pull down transistors in subsequent fabrication steps.

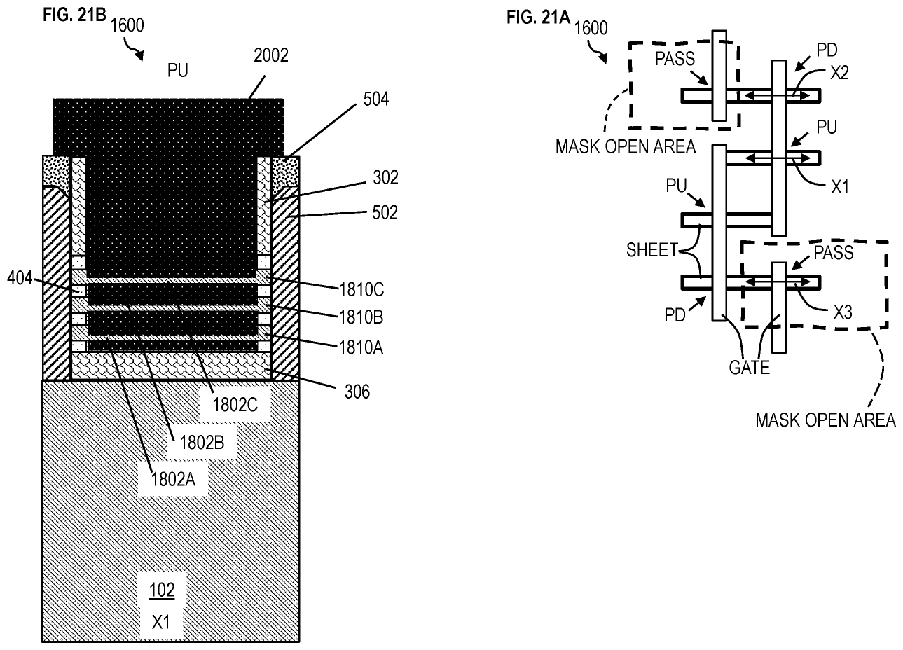

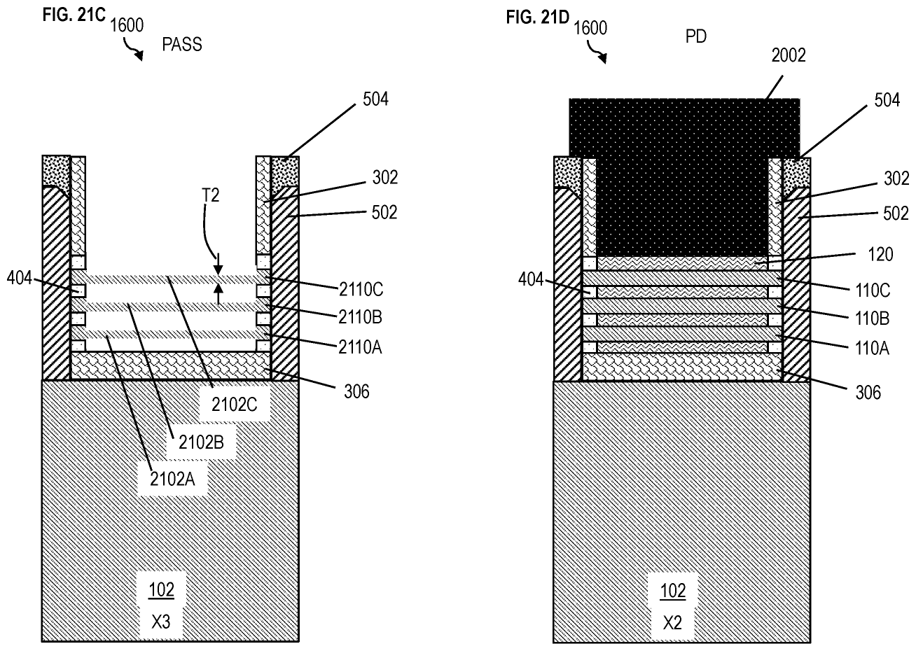

FIGS. 21A, 21B, 21C, and 21D depict the IC 1600 after channel release and silicon trimming. For the exposed sacrificial layers without the protective mask layer 2002, etching is performed to selectively etch the sacrificial layers 120 of the pass gate transistors. An example etchant for the channel release can include HCl. Further etching is performed to respectively reduce the thickness of the semiconductor layers 110A, 110B, and 110C of the pass gate transistors into narrowed semiconductor layers 2102A, 2102B, and 2102C, as seen in FIG. 21C. A wet or dry etchant can be utilized to trim the semiconductor layers 110A, 110B, and 110C. As a result of reducing the thickness of the semiconductor layers 110A, 110B, and 110C to form the narrowed semiconductor layers 2102A. 2102B, and 2102C, end portions 2110A, 2110B, and 2110C are formed and remain underneath the inner spacers 404, as seen in FIG. 21C. The end portions 2110A, 2110B, and 2110C have the original thickness of the nanosheet semiconductor layers 110A, 110B, and 110C prior to trimming. The narrowed semiconductor layers 2102A, 2102B, and 2102C have a thickness T2 that is less than the original thickness of the nanosheet semiconductor layers 110A, 110B, and 110C. The thickness T2 of the narrowed semiconductor layers 2102A, 2102B, and 2102C is greater than the thickness T1 of the narrowed semiconductor layers 1802A, 1802B, and 1802C.

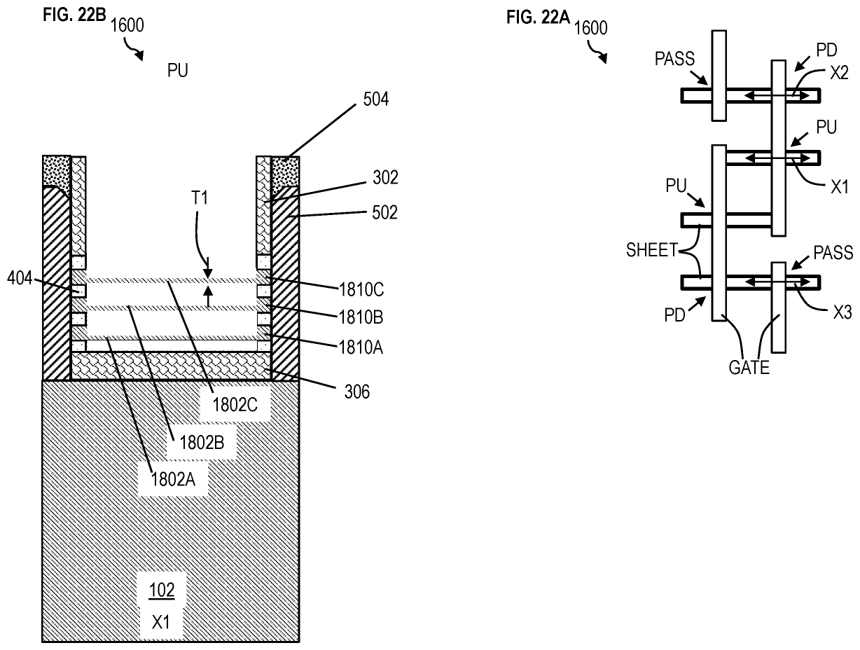

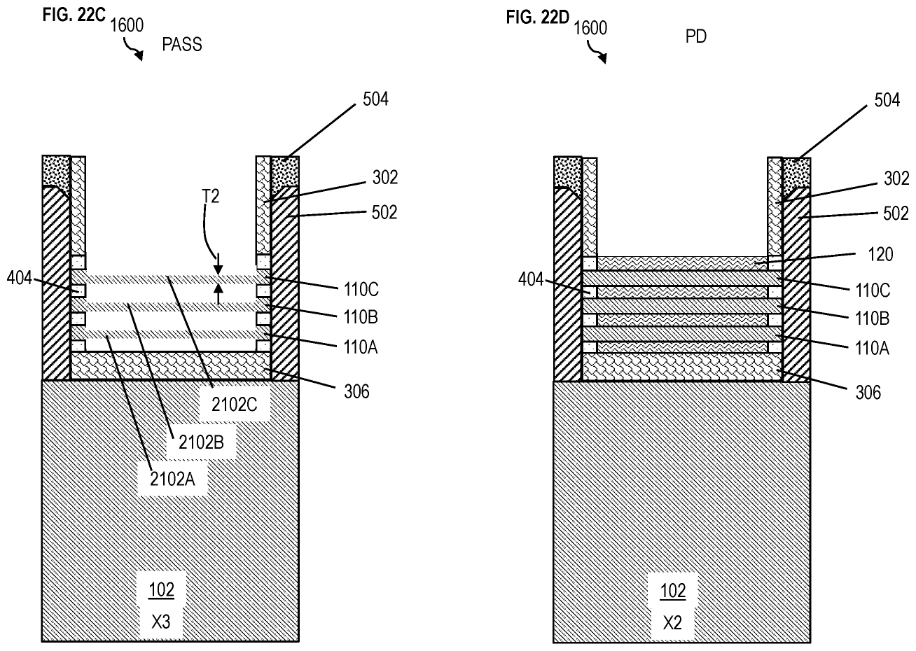

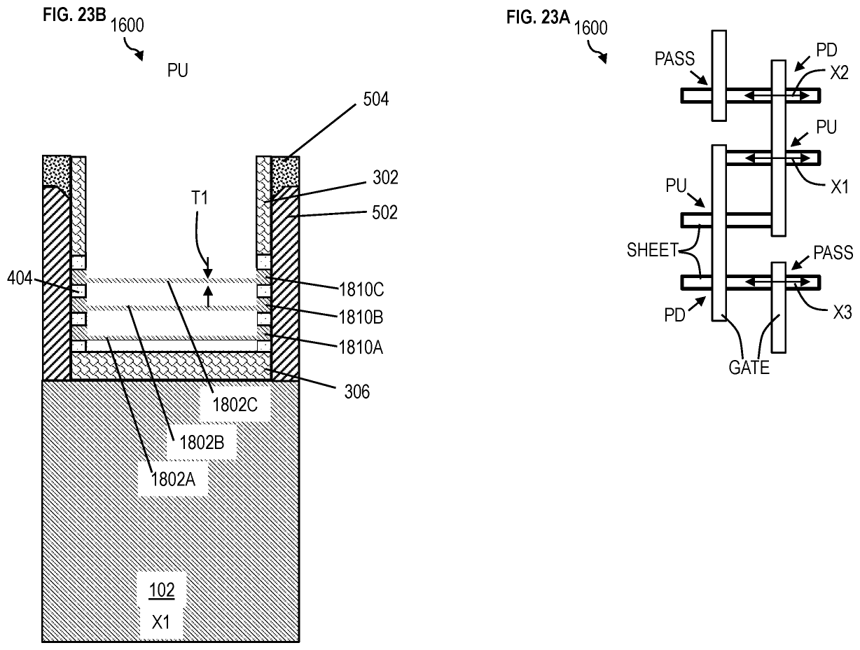

FIGS. 22A, 22B, 22C, and 22D depict the IC 1600 after removal of the mask layer 2002. The mask layer 2002 can be removed, for example, by ashing the OPL.

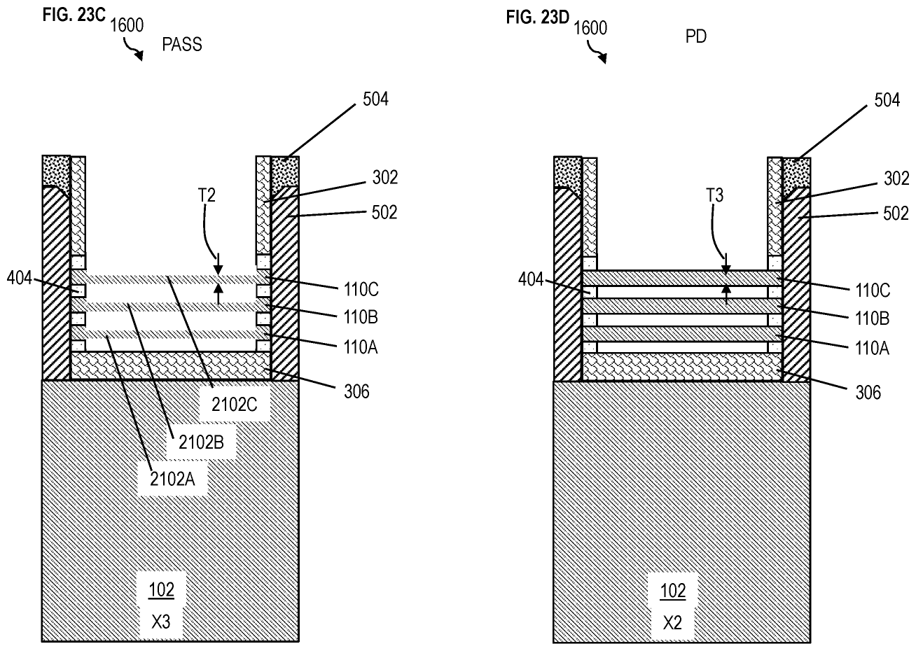

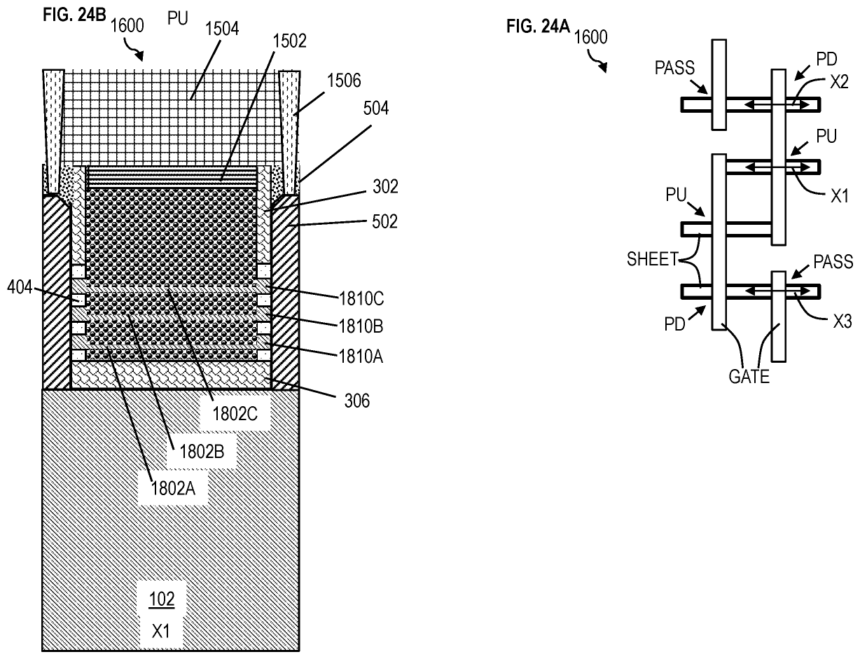

FIGS. 23A, 23B, 23C, and 23D depict the IC 1600 after channel release. Etching is performed to selectively etch the sacrificial layers 120 of the pull down transistors. An example etchant for the channel release can include HCl. At this point, there are three different thicknesses for the semiconductor layers used as the channels in the nanosheet FETs. The narrowed semiconductor layers 1802A, 1802B, and 1802C of the pull up transistors have the thickness T1 as depicted in FIG. 23B, the narrowed semiconductor layers 2102A, 2102B, and 2102C have the thickness T2 as depicted in FIG. 23C, and the semiconductor layers 110A, 110B, and 110C have their original thickness T3 as depicted in FIG. 23D. The original thickness T3 is greater than the thickness T2, while the thickness T2 is greater than the thickness T1.

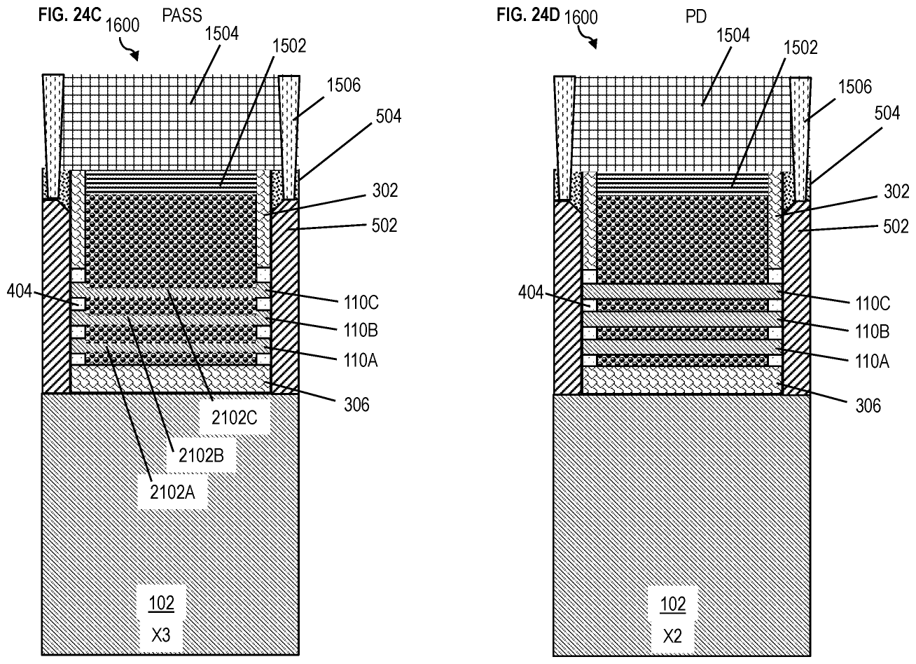

FIGS. 24A, 24B, 24C, and 24D depict the IC 1600 after high-k material deposition, work function material deposition, contact formation, and ILD formation as discussed in FIGS. 14-15. Gate material 1402 is formed around the narrowed semiconductor layers 1802A, 1802B, and 1802C, the narrowed semiconductor layers 2102A, 2102B, and 2102C, and the semiconductor layers 110A, 110B, and 110C. A cap layer 1502 is formed on top of the gate material 1402. Metal contacts 1506 are source/drain contacts that are respectively formed on the epitaxial source/drain regions 502.

In accordance with one or more embodiments, a method of forming a semiconductor structure (e.g., IC 100) is provided. The method includes providing a first transistor (e.g., pull up transistors) having first nanosheets (e.g., semiconductor layers 110) as first channel regions, a second transistor (e.g., pass gates) having second nanosheets (e.g., semiconductor layers 110) as second channel regions, and a third transistor (e.g., semiconductor layers 110) having third nanosheets (e.g., semiconductor layers 110) as third channel regions, the first, second, and third nanosheets being formed of nanosheet material. The method includes providing first end portions 810B and 810C formed of the nanosheet material between first inner spacers 404 in the first transistor, the first end portions 810B and 810C being opposite one another and discontinuous in the first transistor, wherein the first nanosheets (e.g., semiconductor layers 110A in pull up transistors depicted in FIG. 15B) are fewer in number than the second nanosheets (e.g., semiconductor layers 110A and 110B in the pass gate transistors depicted in FIG. 15C).

The second nanosheets (e.g., semiconductor layers 110A and 110B in the pass gate transistors depicted in FIG. 15C) are fewer in number than the third nanosheets (e.g., semiconductor layers 110A, 110B, and 110C in the pull down transistors depicted in FIG. 15D). The first end portions 810C and 810C are adjacent to epitaxial source/drain regions 502. Second end portions 1110C are formed of the nanosheet material between second inner spacers 404 in the second transistor, the second end portions 1110C being opposite one another and discontinuous in the second transistor (e.g., pass gate transistors). The second end portions 1110C are adjacent to epitaxial source/drain regions 502 and fewer in number than the first end portions 810B and 810C. Epitaxial source/drain regions 502 are substantially identical in the first, second, and third transistors. The first, second, and third transistors are formed to utilize different electrical current drive strengths.

In accordance with one or more embodiments, a method of forming a semiconductor structure (e.g., IC 1600). A method includes providing a first transistor (e.g., pull up transistors) having first nanosheets (e.g., semiconductor layers 110) as first channel regions, a second transistor having (e.g., pass gate transistors) second nanosheets (e.g., semiconductor layers 110) as second channel regions, and a third transistor (e.g., pass down transistors) having third nanosheets (e.g., semiconductor layers 110) as third channel regions, the first, second, and third nanosheets being formed of nanosheet material. The method includes reducing an original thickness (e.g., thickness T3) of the first channel regions of the first nanosheets in order to form narrowed first nanosheets (e.g., narrowed semiconductor layers 1802A, 1802B, and 1802C) with a first reduced thickness (e.g., thickness T1) and form first end portions 1810A, 1810B, and 1810C with the original thickness of the first nanosheets, a continuous piece (e.g., as depicted in FIGS. 19B and 24B) of the nanosheet material in the first transistor forming the first end portions and the narrowed first nanosheets.

The first end portions 1810A, 1810B, and 1810C are adjacent to epitaxial source/drain regions 502. The method includes reducing the original thickness of the second channel regions of the second nanosheets in order to form narrowed second nanosheets (e.g., narrowed semiconductor layers 2102A, 2102B, and 2102C with a second reduced thickness (e.g., thickness T2) and form second end portions 2110A, 2110B, and 2110C with the original thickness (e.g., thickness T3) of the second nanosheets. The second end portions 2110A, 2110B, and 2110C are adjacent to epitaxial source/drain regions 502. The second transistor (e.g., pass gate transistors) comprises second channel regions having narrowed second nanosheets 2102A, 2102B, and 2102C with a second reduced thickness (e.g., thickness T2), the second reduced thickness being greater than the first reduced thickness (e.g., thickness T1). The third channel regions of the third nanosheets have the original thickness, the original thickness (e.g., thickness T3) being greater than the first reduced thickness (e.g., thickness T1).

The ILD material can be SiO₂, SiN, a low-k dielectric material or an ultra-low-k dielectric material. Low-k dielectric materials may generally include dielectric materials having a k value of about 3.9 or less. The ultralow-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of #8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
a first transistor having first nanosheets as first channel regions, a second transistor having second nanosheets as second channel regions, and a third transistor having third nanosheets as third channel regions, the first, second, and third nanosheets being formed of a nanosheet material, wherein the first nanosheets are fewer in number than the second nanosheets; and
first end portions formed of the nanosheet material between first inner spacers in the first transistor, the first end portions being opposite one another and discontinuous in the first transistor.

2. The semiconductor structure of claim 1, wherein the second nanosheets are fewer in number than the third nanosheets.

3. The semiconductor structure of claim 1, wherein the first end portions are adjacent to epitaxial source/drain regions.

4. The semiconductor structure of claim 1, wherein second end portions are formed of the nanosheet material between second inner spacers in the second transistor, the second end portions being opposite one another and discontinuous in the second transistor.

5. The semiconductor structure of claim 4, wherein the second end portions are adjacent to epitaxial source/drain regions and fewer in number than the first end portions.

6. The semiconductor structure of claim 1, wherein epitaxial source/drain regions are substantially identical in the first, second, and third transistors.

7. The semiconductor structure of claim 1, wherein the first, second, and third transistors are formed to utilize different electrical current drive strengths.

8. A method comprising:
providing a first transistor having first nanosheets as first channel regions, a second transistor having second nanosheets as second channel regions, and a third transistor having third nanosheets as third channel regions, the first, second, and third nanosheets being formed of a nanosheet material; and
providing first end portions formed of the nanosheet material between first inner spacers in the first transistor, the first end portions being opposite one another and discontinuous in the first transistor, wherein the first nanosheets are fewer in number than the second nanosheets.

9. The method of claim 8, wherein the second nanosheets are fewer in number than the third nanosheets.

10. The method of claim 8, wherein the first end portions are adjacent to epitaxial source/drain regions.

11. The method of claim 8, wherein second end portions are formed of the nanosheet material between second inner spacers in the second transistor, the second end portions being opposite one another and discontinuous in the second transistor.

12. The method of claim 11, wherein the second end portions are adjacent to epitaxial source/drain regions and fewer in number than the first end portions.

13. The method of claim 8, wherein epitaxial source/drain regions are substantially identical in the first, second, and third transistors.

14. The method of claim 8, wherein the first, second, and third transistors are formed to utilize different electrical current drive strengths.

15. A method comprising:
providing a first transistor having first nanosheets as first channel regions, a second transistor having second nanosheets as second channel regions, and a third transistor having third nanosheets as third channel regions, the first, second, and third nanosheets being formed of a nanosheet material; and
reducing an original thickness of the first channel regions of the first nanosheets in order to form narrowed first nanosheets with a first reduced thickness and form first end portions with the original thickness of the first nanosheets, a continuous piece of the nanosheet material in the first transistor forming the first end portions and the narrowed first nanosheets.

16. The method of claim 15, wherein the first end portions are adjacent to epitaxial source/drain regions.

17. The method of claim 15, further comprising reducing the original thickness of the second channel regions of the second nanosheets in order to form narrowed second nanosheets with a second reduced thickness and form second end portions with the original thickness of the second nanosheets.

18. The method of claim 17, wherein the second end portions are adjacent to epitaxial source/drain regions.

19. The method of claim 15, wherein the second transistor comprises the second channel regions having narrowed second nanosheets with a second reduced thickness, the second reduced thickness being greater than the first reduced thickness.

20. The method of claim 15, wherein the third channel regions of the third nanosheets have the original thickness, the original thickness being greater than the first reduced thickness.
